(19) United States
(12) Patent Application Publication
(10) Pub. No.: US 2023/0167582 A1
(43) Pub. Date: Jun. 1, 2023

(54) SiC P-TYPE, AND LOW RESISTIVITY, CRYSTALS, BOULES, WAFERS AND DEVICES, AND METHODS OF MAKING THE SAME

(71) Applicant: Pallidus, Inc., Albany, NY (US)

(72) Inventors: Douglas Dukes, Troy, NY (US); Darren Hansen, Midland, MI (US); Mark Loboda, Bay City, MI (US); Mark Land, Houston, TX (US); Victor Torres, Clifton Park, NY (US); Juan Carlos Rojo, Niskayuan, NY (US)

(73) Assignee: Pallidus, Inc., Albany, NY (US)

(21) Appl. No.: 17/861,186

(22) Filed: Jul. 9, 2022

Related U.S. Application Data
(60) Provisional application No. 63/220,132, filed on Jul. 9, 2021.
(60) Provisional application No. 63/337,088, filed on Apr. 30, 2022.

(51) Int. Cl. C30B 29/36; C30B 25/02

(52) U.S. Cl. CPC C30B 29/36; C30B 25/02

(57) ABSTRACT

A doped SiOC liquid starting material provides a p-type polymer derived ceramic SiC crystalline materials, including boules and wafers. P-type SiC electronic devices. Low resistivity SiC crystals, wafers and boules, having phosphorous as a dopant. Polymer derived ceramic doped SiC shaped charge source materials for vapor deposition growth of doped SiC crystals.

This application claims the right of priority to, and under 35 U.S.C. § 119(e)(1) the benefit of US provisional application serial number the benefit of U.S. provisional application Ser. No. 63/220,132 filed Jul. 9, 2021, and U.S. provisional application Ser. No. 63/337,088 filed Apr. 30, 2022, the entire disclosure of each of which is incorporated herein by reference.

### BACKGROUND OF THE INVENTION

### Field of the Invention

The present inventions relate to p-type SiC crystals, ingots, boules and wafers; low resistivity SiC crystals, ingots, boules and wafers; methods for making p-type SiC crystals, ingots, boules and wafers; methods of making low resistivity SiC crystals, ingots, boules and wafers; and devices made from these wafers and uses for these wafers.

Pure crystalline silicon carbide (SiC) is electrically neutral, i.e., there is a balance of positive and negative charge in the crystalline material. Typically, to be useful in the manufacture of semiconductor diodes and transistors, impurities are added to the SiC crystal during the SiC crystal growth process to create a charge imbalance within the crystal, which impacts the conductivity of the SiC. Impurity atoms which add positive charge to SiC are called donor atoms. In general, donor atoms are identified by the column in the periodic table to the right of the column containing Si and C (e.g., column 15, V A). Typical donor atoms for SiC are nitrogen (N) and phosphorus (P). Impurity atoms which add negative charge to SiC are called acceptor atoms. In general, acceptor atoms are identified by the column in the periodic table to the left of the column containing Si and C (e.g., 13, or III A). Typical acceptor atoms for SiC are boron (B) and aluminum (Al). SiC crystals typically will contain both donor and acceptor atom impurities. For a donor or acceptor impurity atom to impact the net charge in the crystal and become electrically active (i.e. impact the conductivity/resistivity of the crystal), the impurity atom typically must substitute for either a Si or C atom in their location in the crystal, and in this case the impurity atom is called a substitutional impurity. Impurity atoms can also locate at a location between a Si and C atom. In this case the impurity atom is called an interstitial impurity and may not impact the net charge in the crystal, may have a lessor impact on charge, and in some situations does not impact the net charge in the crystal. Thus, the terms “electrically active atomic impurity”, “electrically active impurity”, and “electrically active” are used to describe added atoms to the SiC crystalline material, include substitutional and interstitial, that affect or impact the net charge of the material, e.g., the crystal. Thus, all substitutional impurities are electrically active impurities, and interstitial impurities can be electrically active or non-electrically active impurities. As a result, the atomic concentration (number of impurity atoms to total number of atoms in the crystal) of a donor or acceptor impurity can be equal to or larger than the atomic concentration of the electrically active impurities, e.g., substitutional impurity atoms. When there are more electrically active, e.g., substitutional, donor atoms than electrically active, e.g., substitutional, acceptor atoms the SiC crystal is n-type, n is for negative, i.e., there is an excess of negative charge. Conversely, when there are more electrically active, e.g., substitutional, acceptor atoms than donor atoms, the SiC crystal is p-type, p is for positive, i.e., there is an excess of positive charge in the SiC crystal.

Prior to the present inventions, there has been no availability of industrially manufactured, commercially available p-type SiC substrate with diameter>100 mm for use in manufacturing SiC semiconductor devices. It is believed existing prior attempts at making p-type SiC crystals could not provide a manufacturable process to produce high quality, low defect, p-type SiC materials, such as, SiC crystals, SiC boules and p-type SiC wafers cut from those boules. Thus, prior to the present inventions, the benefits of SiC semiconductor devices having p-type SiC materials, were largely unavailable and were commercial unavailable.

As used herein, unless specified otherwise, there are two types of charge carriers in a semiconductor material, a hole and an electron. A hole can be seen as the “opposite” of an electron. Unlike an electron which has a negative charge, holes have a positive charge that is equal in magnitude to an election, but opposite in polarity to the electron's charge. Holes can sometimes be confusing as they are not physical particles in the way that electrons are, rather they are the absence of an electron in an atom. Holes can move from atom to atom in semi-conductors as electrons leave their positions. Thus, by way of analogy, turning to people standing in a line, on a set of steps. If the person at the front of the line goes up one step, that person leaves a hole. As everyone steps up one step the available step (the hole) moves down the steps. Holes are formed when electrons in atoms move out of the valence band of the atom (typically the outermost electron shell completely filled with electrons) into the conduction band (the area in an atom where electrons can escape easily), which typically happens everywhere in a semiconductor.

As used herein, unless specified otherwise, the terms “p-type”, “p-type wafer”, “p-type crystal”, “p-type boule” and similar such terms shall be given their broadest possible meaning, and would include SiC crystal materials having more electrically active acceptor atom impurities, e.g., substitutional acceptor atom impurities, than electrically active donor atom impurities, e.g., substitutional donor impurity atoms. Thus, for example an SiC crystalline material, having a net amount of electrically active acceptor atoms per unit volume of 1×10¹⁰/cm³ to 1×10²²/cm³, about 1×10¹⁸/cm³ to 1×10²⁰/cm³, about 1×10¹⁸/cm³ to 1×10²³/cm³, about 1×10¹⁸/cm³ to 1×10²⁴/cm³, greater than about 1×10⁹/cm³, greater than about 1×10¹⁵/cm³, greater than about 1×10¹⁸/cm³, and greater than about 1×10¹⁹/cm³ is characterized as a p-type SiC crystal material.

Further, unless specified otherwise, to be considered a p-type SiC crystalline material, the Net Carrier concentration would have an excess of acceptor atomic impurities as given by the equation (1)

N_{C}=N_{D}−N_{A} (1)

where N_{C} is the net concentration of carriers. N_{D}, is the concentration of electrically active donor impurity atoms. N_{A} is the concentration of electrically active acceptor impurity atoms. By convention, N_{C} is negative for a p-type material signifying a lack of electrons.

As used herein, unless specified otherwise, the terms “p-type device”, p-type semiconductor“, and similar such terms are to be given their broadest possible meaning and include any semiconductor, micro-electronic device, or electronic device that has a p-type layer, or is based upon a p-type wafer, chip or substrate.

As used herein, unless specified otherwise, the terms “p⁺”, “p⁺ type” and similar such terms refer to p-type crystalline SiC materials, e.g., p-type boules, wafers, etc., that have a high amount of dopant, e.g., are heavily doped (N_{D}>10¹⁸/cm³) and thus have low resistivities (<0.03 ohm-cm). Thus, p⁺ type materials can have an N_{A} from 10¹⁸/cm³ to about 10²⁰/cm³, N_{A} from 10¹⁸/cm³ to about 10²¹/cm³, an N_{D}>10¹⁹/cm³, about 1×10¹⁸/cm³ to 1×10²³/cm³, about 1×10¹⁸/cm³ to 1×10²⁴/cm³, and an N_{A} of about 10²⁹/cm³. Typically, the resistivities for p⁺ type materials can be at or below 0.03 ohm-cm, less than about 0.025 ohm-cm, less than about 0.020 ohm-cm, less than about 0.015 ohm-cm, from about 0.030 ohm-cm to about 0.01 ohm-cm, from about 0.025 ohm-cm to about 0.008 ohm-cm, and from about 0.020 ohm-cm to about 0.005 ohm-cm.

As used herein, unless specified otherwise, the terms “p⁻”, “p⁻ type” and similar such terms refer to p-type crystalline materials, e.g., p-type boules, wafers, etc., that have a low amount of dopant, e.g., are lightly doped (N_{D}<10¹⁸/cm³) and thus have higher resistivities. Typically, these resistivities are above 0.03 ohm-cm. Thus, p⁻ type materials can have an N_{A} from 10¹⁸/cm³ to about 10¹⁰/cm³, and smaller values. Typically, the resistivities for p⁻ type materials can be from 0.03 ohm-cm to 10⁸ ohm-cm and greater.

As used herein, unless specified otherwise, the terms “n-type”, “n-type wafer”, “n-type crystal”, “n-type boule” and similar such terms shall be given their broadest possible meaning, and would include SiC crystalline materials having a negative charge, SiC crystal materials having more electrically active donor atoms, e.g., substitutional donor atoms impurities than other types of impurity atoms. Thus, for example an SiC crystalline material, having a net amount of electrically active donor atoms per unit volume of 1×10¹⁰/cm³ to 1×10²²/cm³, about 1×10¹⁸/cm³ to 1×10²⁰/cm³, greater than about 1×10⁹/cm³, greater than about 1×10¹⁵/cm³, greater than about 1×10¹⁸/cm³, and greater than about 1×10¹⁹/cm³ is characterized as an n-type SiC crystal material.

Further, unless specified otherwise, to be considered a n-type SiC crystalline material, the Net Carrier concentration would indicate an excess of donor atomic impurities as given by the equation. By convention, N_{C} is positive for an n-type material signifying an excess of electrons.

The terms “n⁺”, “n⁺ type” and similar such terms refer to n-type materials, e.g., n-type boules, wafers, etc., that have a high amount of dopant, e.g., are heavily doped (N_{A}>10¹⁸/cm³) and thus have low resistivities (<0.03 ohm-cm). Typically, these resistivities can be at or below 0.03 ohm-cm.

The terms “n⁻”, “n⁻ type” and similar such terms refer to n-type materials, e.g., n-type boules, wafers, etc., that have a low amount of dopant, e.g., are lightly doped (N_{A}<10¹⁸/cm³) and thus have higher resistivities. Typically, these resistivities can be above 0.03 ohm-cm, and general at or above 0.03 ohm-cm.

As used herein, unless specified otherwise, the terms “physical holes”, “physical void” and “physical cavity”, refer to physical properties, not electric, and are used in the common ordinary manner, such as meaning a hollow place in a solid body or surface, the absence of material in a structure or surface, and an empty space within a surface or solid.

As used herein, unless specified otherwise, “Vapor Deposition” (“VD”), “vapor deposition technology”, “vapor deposition process” and similar such terms are to be given their broadest meaning, and would include for example processes where a solid or liquid starting material is transformed into a gas or vapor state, and then the gas or vapor is deposited to form, e.g., grow, a solid material. As used herein vapor deposition technology would include growth by epitaxy, where the layer is provided from a vapor or gaseous phase. Further types of vapor deposition technology include: Chemical Vapor Deposition (“CVD”); Physical Vapor Deposition (“PVD”), plasma enhanced CVD, Physical Vapor Transport (“PVT”) and others. Examples of vapor deposition devices would include a hot wall chemical vapor deposition reactor, a multiwafer chemical vapor deposition reactor, a chemical vapor deposition chimney reactor. Physical Vapor Transport (PVT) means and requires the use of at least one solid starting material that is sublimed to provide a vapor (e.g., a flux) for growth of a crystal.

As used herein, unless specified otherwise the term “vaporization temperature” is to be given its broadest possible meaning and includes that temperature at which the material transitions from a liquid to a gas state, transitions from a solid to a gas state, or both (e.g., the solid to liquid to gas transition occurs over a very small temperature range, e.g., a range of less than about 20° C., less than about 10° C., and less than about 5° C.). Unless specifically stated otherwise, the vaporization temperature would be the temperatures corresponding to any particular pressures, e.g., one atmosphere, 0.5 atmosphere, where such transition occurs. When discussing the vaporization temperature of a material in a particular application, method, or being used in a particular device, such as a PVT device, the vaporization temperature would be at the pressure used, or typically used, in that application, method or device, unless expressly stated otherwise.

Silicon carbide does not generally have a liquid phase, and is not in a liquid phase in typical PVT process conditions, instead it sublimes, under vacuum, at temperatures above about 1,700° C. (It is noted that at very high pressure SiC can exist in a liquid phase.) Typically, in industrial and commercial applications conditions are established so that the sublimation takes place at temperatures of about 2,500° C. and above. When silicon carbide sublimes it typically forms a vapor flux consisting of various species of silicon and carbon, and the components of the vapor flux are a function of the source material, as well as, the temperature and pressure. The present inventions, however, among other things, provide the capability to control the ratio of these components, through the selection of liquid starting materials (e.g., polysilocarb precursors), in addition to, the use of source materials (e.g., shaped charges), as well as, temperature and pressure during the PVT process.

As used herein, unless specified otherwise, the terms “crystal”, “ingot” and “boule”, and similar such terms should be given their broadest possible meaning and refer to crystalline structures that have a diameter from about 50 mm to about 250 mm, a diameter larger than 100 mm, a diameter larger than 250 mm, and typically a diameter of about 150 mm; and that have a height (i.e., distance from seed end to tail end) of about 25 mm to about 250 mm, a height of about 75 mm to about 150 mm, a height of 75 mm and greater, a height of about 100 mm and greater, a height of about 150 mm and greater, and typically a height of about 100 mm to about 150 mm. The term “crystal” generally refers to the structure that is initially grown and then removed from the growth apparatus. The term “ingot” generally refers to a crystal that has had one, or both, of its ends processed, e.g., flattened. The term “boule” generally refers to an ingot that has been further processes, e.g., a flat formed on the boule, and is ready for the wafering processes (i.e., fabrication of wafers from the boule). Typically, crystals are grown in vapor deposition apparatus using a vapor deposition processes, and in particular a PVT apparatus and processes.

Unless, expressly provided otherwise, or clear from the context, the terms crystal, ingot and boule, are generally interchangeable as used in this Specification; and in particular, the description in this Specification of the properties, crystalline structure, macro and micro defects, and composition of one is generally applicable to the others.

As used herein, unless specified otherwise, the terms “wafer”, “SiC wafer”, “p-type SiC wafer”, “n-type SiC wafer” and similar such terms, refers to a crystalline material, which is a structure that was cut from a larger structure of the same crystalline material (e.g., a p-type SiC wafer is cut from a p-type SiC boule). Typically, the wafer 700 a disc like structure and can be circular, or circular or semicircular shape 705, and may have a flat, or more than one flat. The wafer has a top or top surface, a bottom or bottom surface and a thickness. The outer edge of the wafer can be tapered, beveled, chamfered, square, round, etc.

Typically SiC wafers are formed by cutting the wafers generally transverse to the c-axis (growth axis) of a larger crystal, e.g., a boule. Typically, the wafers can be on the growth axis (i.e., on axis) or a few degrees of this axis (i.e., off axis), typically, for off axis wafers, about 0.1 to about 5 degrees off the growth axis. The wafers can have a thickness of from about 80 μm to about 600 μm, and a diameter of from about 50 mm to about 250 mm, with diameters of about 150 mm being preferred. When cut on, or slightly off axis, the SiC wafers typically have a carbon face or surface and a silicon face or surface. Wafers may also be cut along the growth axis, and in any other orientation to the growth axis.

In general, prior to the development of commercial SiC MOSFETs, the power industry (>500V) was primarily based on the use of Silicon (Si) IGBTs. These are bipolar devices and have low conduction losses allowing them to handle high currents (amps) and powers (watts, or W). However, they suffer from high power losses during the turn-off stage (the transition between conducting and blocking), limiting the frequency at which they can be operated. The frequency of operation is important because, the higher the frequency, the smaller the passive elements of the converters/inverters are (e.g., inductors), which helps reducing the volume and weight of the device. Reducing the volume, weight and both of these devices (MOSFETs and IGBTs) has been a long standing problem of the art, and are important metrics for end users. MOFETS are unipolar devices, and therefore, they provide lower switching losses (particularly during the turn-off stage.) However, they suffer from higher on-resistance (conduction losses) which increases with voltage so that, at higher voltages (for Si is >500V) IGBTs are favored. Thus, the art has been presented with a long standing and unsolved paradigm of optimizing (i.e., minimizing) both conduction losses and transition losses in a semiconductor device.

Further, the transition of silicon based devices to SiC based devices has faced substantial and long standing problems. In particular, the transition for p-type silicon type devices to SiC type devices (e.g., n-type for these initial prior attempts) requires significant expense, time and difficulty to redesign the p-type silicon type device, e.g., circuitry, masks, configurations, etc., so that n-type SiC can be used. The prior arts inability to provide high quality p-type SiC wafers has left this long-standing problem and need unsolved.

The history of power electronics devices and circuits starts with semi devices made from silicon.

Many designs of power circuits employ designs, as well as p-channel and n-channel field effect transistors, the most common transistor is the MOSFET, or metal oxide semiconductor field effect transistor. As used herein, unless specified otherwise, a p-channel MOSFET is a type of MOSFET in which the channel of the MOSFET is composed of a majority of holes as current carriers. When the MOSFET is activated and is on, the majority of the current flowing are holes moving through the channels. Another type of MOSFET is an n-channel MOSFET, in which the majority of current carriers are electrons. An n-channel or p-channel MOSFET can be made two different ways, an enhancement-type MOSFETs or a depletion-type MOSFETs.

A depletion-type MOSFET is normally on (maximum current flows from source to drain) when no difference in voltage exists between the gate and source terminals. However, if a voltage is applied to its gate lead, the drain-source channel becomes more resistive, until the gate voltage is so high, the transistor completely shuts off. An enhancement-type MOSFET is the opposite. It is normally off when the gate-source voltage is 0V (VGS=0). However, if a voltage is applied to its gate lead, the drain-source channel becomes less resistive.

Typical applications of power devices are the design and manufacture of power circuits, i.e. inverter, converters, and power supplies. These circuits are designed using n-channel MOSFETs or p-channel MOSFETS or both. An example where both types are required is an H-bridge power drive circuit, where the function is to drive current through the load in either direction (i.e. to drive a DC motor forwards or backwards such as in an electric automated guided vehicle or a motor in an all-electric vehicle).

To increase the energy efficiency in modern power management circuits today designers now employ silicon carbide MOSFETS based on 4H—SiC crystalline substrates. Silicon carbide MOSFETs offer the opportunity to design circuits operating at higher voltage and high frequency compared to circuits using silicon MOSFETs. With SiC MOSFETS typically the power circuits discussed above can operate in ranges of voltage from 600 V to higher than 10 kV, and amperage of 5 A to higher than 200 A.

Today MOSFETs made SiC can only be fabricated with n-type SiC substrates, as there is currently no available commercial supply of p-type SiC substrates. As a result, most SiC MOSFETS are made as n-channel devices. Because, to date only SiC MOSFET using an n-type substrate have been commercially available, SiC MOSFETs cannot be deployed across the full range of power circuit applications.

There has been a long standing need for an commercially viable n-channel IGBT, a variant of a MOSFET transistor, because this device could provide lower on-resistance and/or higher blocking voltage than its p-channel counterpart. Moreover, n-channel devices, with their positive voltage polarities and similarities to conventional power MOSFETs, may be more attractive from a systems point of view. To date such devices have been fabricated using p-type SiC materials formed as an epitaxial layer on an n-type SiC substrate, followed by removal of the substrate by grinding. These devices have proven to be unsatisfactory for several reasons, including due to the difficultly of requiring substrate removal. The present inventions, among other things provides the ability to provide such SiC IGBT devices that are simple to fabricate and commercially acceptable.

There has been a long standing need for an SiC LDMOSFETS (lateral metal-oxide-semiconductor field effect transistor). These devices were developed in silicon for high-power applications such as cellular and UHF broadcast transmission has increased enormously. This is because Si LDMOSFETs offer higher gain and better linearity than bipolar devices. Yet, prior to the present inventions, this design cannot be realized in SiC, since there are only n-type SiC substrates and historically any p-type epitaxial formed SiC substrates have too high resistivity compared to silicon, leading to undesirable LDMOSFET device performance.

Generally, power MOSFETs tend to show better performance when fabricated with n-channels rather than p-channels. However, to achieve even more enhanced performance, such devices typically need to be grown epitaxially on low-resistivity p-type substrates. However, at present, commercially available p-type 4H—SiC substrates have relatively high resistivity (˜2.5 ohm-cm), which is about two orders of magnitude higher than that of the n-type substrate. The advantages of n-channel SiC devices, have long been sought after, but have not been realized, because of the high resistivity found in prior p-type substrates. Thus, the p-type wafers of the present invention provide low resistivities that solve this long standing need and enable n-channel SiC devices with improved performance relative to devices fabricated with n-type SiC substrates.

As used herein, unless specified otherwise, the terms “specific gravity”, which is also called “apparent density”, should be given their broadest possible meanings, and generally mean weight per until volume of a structure, e.g., volumetric shape of material. This property would include internal porosity of a particle as part of its volume. It can be measured with a low viscosity fluid that wets the particle surface, among other techniques.

As used herein, unless specified otherwise, the term “actual density”, which may also be called “true density”, should be given their broadest possible meanings, and general mean weight per unit volume of a material, when there are no voids present in that material. This measurement and property essentially eliminates (i.e., below detectable levels by standard measuring techniques) any internal porosity from the material, e.g., it does not include any voids in the material.

As used herein, unless stated otherwise, “room temperature” is 25° C. And, “standard ambient temperature and pressure” is 25° C. and 1 atmosphere. Unless expressly stated otherwise all tests, test results, physical properties, and values that are temperature dependent, pressure dependent, or both, are provided at standard ambient temperature and pressure, this would include viscosities.

Generally, the term “about” and the symbol “—” as used herein unless stated otherwise is meant to encompass the larger of the variance or range of ±10% and the experimental or instrument error associated with obtaining the stated value.

As used herein, unless specified otherwise the terms %, weight % and mass % are used interchangeably and refer to the weight of a first component as a percentage of the weight of the total, e.g., formulation, mixture, preform, material, structure or product. The usage X/Y or XY indicates weight % of X and the weight % of Y in the formulation, unless expressly provided otherwise. The usage X/Y/Z or XYZ indicates the weight % of X, weight % of Y and weight % of Z in the formulation, unless expressly provided otherwise.

As used herein, unless specified otherwise “volume %” and “% volume” and similar such terms refer to the volume of a first component as a percentage of the volume of the total, e.g., formulation, mixture, preform, material, structure or product.

As used herein, unless expressly stated otherwise, the terms “source material”, as used in the context of boule growth, vapor deposition apparatus, epitaxy, and crystal growth and deposition process, should be given its broadest definition possible, and refers to the powdered SiC material, SiC volumetric shape (e.g., a shaped charge), or other form of solid SiC material, that is placed in the growth chamber, or otherwise placed in an apparatus for crystal growth, epitaxy, or SiC vapor deposition, and that forms the flux.

As used herein, the terms such as “purity”, “purity levels”, “impurities” and “contaminants”, should be viewed in contact, and generally relate to materials that are undesirable, and were not intentionally added to the SiC material or the polymer derived process to make the SiC crystal. These terms do not include the dopant, (e.g., impurity atom(s), atomic impurity, substitutional impurity, interstitial impurity, electrically active impurity and similar such terms), or other element or material that is intentionally added to, or incorporated into the SiC crystal, to provide or effect electric charge, semiconductor properties, or other properties and features of the SiC crystal. These terms do not include any predetermined material that was intentionally incorporated into or combined with the starting materials, the polysilocarb precursors, the cured material, the first ceramic material, the source material, and one or more of these, to provide a feature to the SiC crystal, and in particular the SiC wafer. The amount of the dopant would be considered (i.e., counted) as a part of the SiOC or SiC material in making a determination of purity and purity levels. Thus, as so defined, and as used herein, a dopant, or doping material, is not an “impurity.” In this manner, for example, a doped (e.g., with atomic impurities) SiOC material or a doped (e.g., with atomic impurities) SiC material having only dopant and Si, O and C, or dopant and only Si and C, would be 100% pure.

As used herein, unless expressly stated otherwise, the terms “existing material”, “prior material”, “current material”, “currently available material”, “existing vapor deposition apparatus”, “current vapor deposition apparatus”, and similar such terms, refer to source material and apparatus that are, or were, in existence prior to the present inventions. The use of this term is not to be taken as, and is not, an admission of prior art. It is merely to describe the current state of the art as a base line, or reference point, by which the significant and ground breaking improvements of the embodiments of the present inventions can be evaluated, contrasted and measured.

This Background of the Invention section is intended to introduce various aspects of the art, which may be associated with embodiments of the present inventions. Thus, the forgoing discussion in this section provides a framework for better understanding the present inventions, and is not to be viewed as an admission of prior art.

### SUMMARY

There has been an unfulfilled, long-standing and ever-increasing need for high temperature, high capacity and high-performance semiconductor devices, power devices and electronics. Silicon Carbide (SiC) wafers provide a substrate that meets the performance features, e.g., high temperatures, power, band gap, etc., that are preferred and needed for these applications. Prior to the present inventions, however, a p-type SiC crystal, p-SiC ingot, p-type SiC boule, and p-type SiC wafers made from such a boule, have not been commercially obtainable, and have been largely unobtainable. In particular, such p-type materials have not been obtainable by PVT processes. Thus, the advantages, benefits and potential of semiconductor devices based upon a p-type SiC wafer have not been realized, and in particular, utilized in a commercially and economically acceptable manner.

An additional long standing problem with prior attempts to dope SiC, including incorporating electrically active acceptor atoms to the SiC crystal, was a lack of uniformity, both side to side and top to bottom in the crystal or wafer. The present inventions address and solve this long standing problem by providing methods, source materials that provide crystals that have highly uniform distribution of the electrically active atomic impurities both side to side and top to bottom in embodiments of the doped SiC crystals and wafers of the present inventions.

The present inventions, among other things, solves these long-standing needs, by providing formulations, methods and apparatus to obtain p-type SiC materials and semiconductor devices utilizing those p-type SiC materials.

The present inventions, among other things, solve these problems and long-standing needs by providing the compositions, materials, articles of manufacture, devices and processes taught, disclosed and claimed herein.

The present inventions, among other things, solve these problems and long-standing needs by providing high quality, low defect, p-type SiC materials, including p-type SiC crystals, p-type SiC ingots, p-type SiC boules and p-type SiC wafers obtained from those boules. The present inventions, among other things, solve these problems and long-standing needs by providing p-type SiC materials, including p-type SiC crystals, p-type SiC ingots, p-type boules and p-type wafers, which are suitable or viable for economical fabrication, commercial fabrication or both, of semiconductor devices. The present inventions, among other things, solve these problems and long-standing needs by providing the benefits of SiC semiconductor devices having p-type SiC materials, and in particular, providing these devices in an economical and commercially viable manner, so that their use and benefits can be widely available.

There has also been a long standing and unsolved need for low resistivity SiC materials, including low resistivity SiC crystals, SiC ingots, SiC boules and SiC wafers obtained from those boules, and in particular low resistivity SiC wafers and the devices that can be built upon or from these wafers. These low resistivity wafers can be p-type or n-type wafers. The present inventions, among other things, solve these problems and long-standing needs by providing low resistivity SiC materials, including low resistivity SiC crystals, SiC ingots, boules and wafers, which are suitable or viable for economical fabrication, commercial fabrication or both, of semiconductor devices.

Thus, there is provided a doped polysilocarb precursor material, for use in making a doped SiC crystal, the precursor material having: a dopant, wherein the dopant has a number of donor atoms, a number of acceptor atoms or both; silicon, carbon, and oxygen; wherein the dopant is about 10% or less by weight of a total weight of the doped polysilocarb precursor material; wherein the dopant is covalently bonded to at least one of silicon, carbon or oxygen; wherein the doped polysilocarb precursor material defines a potential net carrier concentration (pNC); wherein pNC=the number of donor atoms−the number of acceptor atoms.

In addition, there is provided a doped shaped charge source material, for use in making a p-type SiC crystal, the shaped charge source material having: a porous matrix having Si, C and a number of impurity atoms, wherein the impurity atoms include a number of donor atoms, a number of acceptor atoms or both; wherein the impurity atoms are less than 5% by weight of a total weight of the doped shaped charge source material; wherein the doped shaped charge source material defines a potential net carrier concentration (pNC); wherein pNC=the number of donor atoms−the number of acceptor atoms.

In addition, there is provided a method of making a doped shape charge source material for use in making a p-type SiC crystal, the method having: providing a liquid precursor formulation, wherein the formulation has silicon, carbon, oxygen and a dopant; and the dopant has acceptor atoms; curing the liquid precursor formulation to thereby provide a cured solid precursor, wherein the cured solid precursor formulation has silicon, carbon, oxygen and the acceptor atoms; wherein the acceptor atoms are held by the cured solid precursor; pyrolizing the cured solid precursor to thereby provide a doped SiC precursor; mixing the doped SiC precursor with a binder and with an additional source of the acceptor atoms, to thereby provided a mixture; forming the mixture into a volumetric shape; curing the volumetric shape; and, pyrolizing the volumetric shape to provide a shaped charge source material consisting essentially of silicon, carbon and the acceptor atoms.

Furthermore, there is provided a method of making a doped shape charge source material for use in making a low resistivity n-type SiC crystal, the method including the following steps: providing a liquid precursor formulation, wherein the formulation has silicon, carbon, oxygen and a dopant; and the dopant has donor atoms; curing the liquid precursor formulation to thereby: provided a cured solid precursor, wherein the cured solid precursor formulation has silicon, carbon, oxygen and the acceptor atoms; wherein the donor atoms are held by the cured solid precursor; mixing the cured solid precursor with a binder and with an additional source of the donor atoms, to thereby provided a mixture; forming the mixture into a volumetric shape; and, pyrolizing the volumetric shape to provide a shaped charge source material consisting essentially of silicon, carbon and the donor atoms.

Still further, there is provided a liquid doped polysilocarb precursor material, for use in making a p-type SiC crystal, the liquid doped polysilocarb precursor material having: a dopant, wherein the dopant has one or more elements selected from Group 13 of the periodic table, whereby the selected elements provide a number of acceptor atoms; silicon, carbon, and oxygen; wherein the dopant is less than 10% by weight of a total weight of the liquid doped polysilocarb precursor material; and, wherein the liquid doped polysilocarb precursor material defines a negative potential net carrier concentration (pNC); wherein pNC=the number of donor atoms−a number of acceptor atoms.

In addition, there is provided a liquid doped polysilocarb precursor material, for use in making a low resistivity n-type SiC crystal, the liquid doped polysilocarb precursor material having: a dopant, wherein the dopant has one or more elements selected from Group 15 of the periodic table, whereby the selected elements provide a number of donor atoms; silicon, carbon, and oxygen; wherein the dopant is less than 10% by weight of a total weight of the liquid doped polysilocarb precursor material; and, wherein the liquid doped polysilocarb precursor material defines a positive potential net carrier concentration (pNC); wherein pNC=the number of donor atoms−a number of acceptor atoms.

There is further provided these methods, compositions and materials having one or more of the following features: wherein the pNC is positive; wherein there are at least 1×10¹⁸ more donor atoms than acceptor atoms; wherein the number of acceptor atoms is less than 1×10¹⁴; wherein the number of acceptor atoms is less than 1×10¹⁰; wherein the donor atoms are selected from one or more of the elements in Group 15 of the periodic table; wherein the donor atoms include phosphorous; and, wherein the donor atoms consist essentially of phosphorous; wherein the donor atom includes phosphorous; wherein the covalent bond is formed with phosphorous; and, the polysilocarb precursor further having one or more of: (a) ˜Si—O—P—R, where R is an alkyl group, a phenyl group, or a styrenyl group; (b) ˜Si—C—C—P—R, wherein R is an alkene group, a styrenyl group, an alkyl group or a phenyl group; and, (c) (˜Si—O)₃—P═O (“˜Si” and “Si˜” as used in these reactions, represents the reactive Si functional group, or moiety, that is attached to a larger structure such as a polymeric backbone, or ligand backbone, which larger structure is not shown in the reactions); wherein the precursor material is a cured solid material; wherein the impurity atoms are fixed in the porous matrix; and, wherein the impurity atoms are fixed in and held by the porous matrix.

Moreover, there is provided these methods, compositions and materials having one or more of the following features: wherein the pNC is negative; wherein there are at least 1×10¹⁸ more acceptor atoms than donor atoms; wherein the number of donor atoms is less than 1×10¹⁴; wherein the number of donor atoms is less than 1×10¹⁰; wherein the acceptor atoms are selected from one or more of the elements in Group 13 of the periodic table; wherein the acceptor atoms include boron; wherein the acceptor atoms consist essentially of boron; wherein the acceptor atoms include aluminum; wherein the acceptor atoms consist essentially of aluminum; wherein the acceptor atoms include aluminum; and wherein the precursor material contains no alloys, and is thereby alloy free; wherein the acceptor atoms consist essentially of aluminum; and wherein the precursor material contains no alloys, and is thereby alloy free; wherein the precursor material contains no alloys, and is thereby alloy free; wherein the acceptor atom includes aluminum; wherein the covalent bond is formed with aluminum; and, the polysilocarb precursor further having one or more of: (a) 2Al—(O—Si—)₃; (b) 2Al—(O—Si—)₃; and, (c) Al₂O₃; wherein the acceptor atom includes boron; wherein the covalent bond is formed with boron; and, the polysilocarb precursor further having one or more of: (a) 2B—(O—Si—)₃; and, (b) B—C—C—Si˜ (“—Si” and “Si—” as used in these reactions, represents the reactive Si functional group, or moiety, that is attached to a larger structure such as a polymeric backbone, or ligand backbone, which larger structure is not shown in the reactions); wherein the precursor material is a cured solid material; wherein the impurity atoms are fixed in the porous matrix; and, wherein the impurity atoms are fixed in and held by the porous matrix.

Additionally, there is provided these methods, compositions and materials having one or more of the following features: wherein the impurity atoms are fixed in the porous matrix; wherein the impurity atoms are fixed in and held by the porous matrix.

Further, there is provided these methods, compositions and materials having one or more of the following features: wherein the dopant is less than 8% by weight of a total weight of the liquid doped polysilocarb precursor material; wherein the dopant is less than 3% by weight of a total weight of the liquid doped polysilocarb precursor material; wherein the weight percent of the dopant is from about 2% to about 5%; wherein the weight percent of the dopant is less than about 5%; wherein the weight percent of the dopant is from about 1% to about 5%; wherein the weight percent of the impurity atom is from about 0.2% to about 2%; wherein the weight percent of the impurity atom is less than about 1%; wherein the weight percent of the impurity atom is from about 0.5% to about 1%.

### BRIEF DESCRIPTION OF THE DRAWINGS

FIG. 1 is a photograph of an embodiment of a 150 mm p-type SiC crystal in accordance with the present inventions.

FIG. 2A is a plan schematic view of an embodiment of a doped SiC wafer in accordance with the present inventions.

FIG. 2B is a cross sectional schematic view of the wafer of FIG. 2A taken along line B-B.

FIG. 3 is a process flow diagram of an embodiment of a system and method in accordance with the present inventions.

FIG. 4 is a schematic cross sectional schematic view of an embodiment of a vapor deposition apparatus and process in accordance with the present inventions.

FIG. 5 is a schematic cross sectional schematic view of an embodiment of an N-channel E-MOSFET device utilizing a p-type SiC wafer in accordance with the present inventions.

FIG. 6 is a schematic cross sectional view of a schematic of an embodiment of an P-channel E-MOSFET device utilizing a p-type SiC wafer in accordance with the present inventions.

FIG. 7 is a schematic cross sectional schematic view of an embodiment of an N-channel D-MOSFET device utilizing a p-type SiC wafer in accordance with the present inventions.

FIG. 8 is a schematic cross sectional schematic view of an embodiment of a P-channel D-MOSFET device utilizing a p-type SiC wafer in accordance with the present inventions.

FIG. 9 is a schematic cross sectional schematic view of an embodiment of an IGBT device utilizing a p-type SiC wafer in accordance with the present inventions.

FIG. 10 is a schematic cross sectional schematic view of an embodiment of a Laterally Diffused MOSFET (LDMOS) device utilizing a p-type SiC wafer in accordance with the present inventions.

FIG. 11 is a schematic cross sectional schematic view of an embodiment of a VMOS MOSFET device utilizing a p-type SiC wafer in accordance with the present inventions.

FIG. 12 is a schematic cross sectional schematic view of an embodiment of an UMOS MOSFET device utilizing a p-type SiC wafer in accordance with the present inventions.

FIG. 13 is a schematic cross sectional schematic view of an embodiment of an IGTB device utilizing a p-type SiC wafer in accordance with the present inventions.

FIG. 14 is a schematic cross sectional view of an embodiment of a CMOS compound device utilizing a p-type SiC wafer in accordance with the present inventions.

FIG. 15 is a schematic cross sectional view of an embodiment of a flash memory device utilizing a p-type SiC wafer in accordance with the present inventions.

FIG. 16 is a schematic cross sectional view of a f CMOS compound device utilizing a p-type SiC wafer in accordance with the present inventions.

### DESCRIPTION OF THE PREFERRED EMBODIMENTS

In general, the present inventions relate to Silicon Carbide (SiC) crystals, ingots, boules and wafers, processes to make those items, and devices that are made from, or based upon, those wafers.

In general, embodiments of the present inventions relate to these crystals, ingots, boules and wafers that are made using sublimation growth process, such as physical vapor transport (PVT) and apparatus to execute the sublimation growth process, (e.g., PVT apparatus), with a starting material comprising a polysilocarb precursor material in a polymer derived ceramic based process.

In general, embodiments the present inventions relate to p-type SiC crystals, which include ingots, boules and wafers, processes to make those p-type items, and devices that are made from, or based upon, those p-type wafers. In particular, embodiments of the present inventions relate to cubic p-type SiC crystals, ingots, boules and wafers, processes to make those p-type items, and devices that are made from, or based upon, those p-type wafers. In particular, embodiments of the present inventions relate to hexagonal p-type SiC crystals, including ingots, boules and wafers, processes to make those p-type items, and devices that are made from, or based upon, those p-type wafers.

In general, embodiments the present inventions relate to low resistivity SiC crystals, including ingots, boules, and wafers, processes to make those items, and devices that are made from, or based upon, those wafers. In particular, in embodiments, the present inventions relate to n-type and p-type SiC wafers having resistivities of 0.010 ohm-cm and less, and preferably resistivities of 0.005 ohm-cm and less. These low resistivity wafers can be p-type or n-type wafers. In embodiments, these low resistivity wafers have cubic or hexagonal crystalline structures, each of which are also p-type or n-type wafers.

In general, embodiments of the present inventions are based upon, or include polymer derived ceramic (“PDC”) materials, products and applications that are using, based on, or constituting of PDC materials generally. Examples of PDC materials, formulations, precursors, starting materials, as well as, apparatus and methods for making such materials are found, for example, in U.S. Pat. Nos. 9,657,409, 9,815,943, 10,091,370, 10,322,936 and 11,014,819, as well as, US Patent Publication Nos. 2018/0290893, and U.S. Pat. Nos. 9,499,677, 9,481,781, 8,742,008, 8,119,057, 7,714,092, 7,087,656, 5,153,295, and 4,657,991, the entire disclosures of each of which are incorporated herein by reference.

Preferred PDCs are “polysilocarb” materials, which are PDC materials containing silicon (Si), oxygen (O) and carbon (C). Polysilocarb materials and methods of making those materials are disclosed and taught in U.S. Pat. Nos. 9,815,943, 9,657,409, 10,322,936, 10,753,010, 11,014,819 and 11,091,370 and US Patent Publication No. 2018/0290893, the entire disclosures of each of which are incorporated herein by reference.

In general, embodiments of the present inventions involve a liquid-to-solid-to-ceramic-to-crystal processes, using a PDC liquid precursor material, that is then cured to a solid material (e.g., plastic like material, the cured material). This cured sold PDC material is converted (e.g., pyrolized) into a first PDC ceramic material, and then this first ceramic material is converted (e.g., pyrolized) to a PDC SiC source material. Typically, these steps or transitions are performed as separate heating operations, however, they can be performed in a single heating operation. The PDC SiC source material can be further formed into a shape charge source material. The PDC SiC source material is then used to grow (e.g., by vapor deposition and preferably PVT) a PDC SiC crystal. Typically, the precursor materials are liquids, however, they can be solids, dissolved solids, and molten.

In general, one or more dopants (e.g., an added material intended to impart a predetermined property or properties to the SiC crystalline material, e.g., crystals, ingots, boules and wafers, such as atomic impurities) can be added to the PDC material. These dopants are selected to provide predetermined properties, features or both (e.g., electrical or semi-conductor related properties or features) to the SiC crystal, which then includes the ingot, the boule and the wafer, that is grown or made from the PDC precursor. In preferred embodiments, the predetermined electrical or semi-conductor properties or features include, for example: resistivity; conductivity; crystal location (substitutional or interstitial) and distribution of donor atoms (i.e., absence of an electron) and electrons; concentration, crystal location and distribution of electrically active atomic impurities; the concentration, crystal location, ratio and distribution of substitutional atomic impurities and interstitial atomic impurities; N_{C} values; N_{A} values; and, N_{D} values, carrier concentrations, Ne, Nh; and, changes within the electronic band structure to the valence or conduction band energies or fermi energy(s). These features would include p-type, and low resistivity n-type or p-type crystals, as well as, such items having cubic or hexagonal crystalline structures.

The dopant can be added to the liquid PDC precursor material, to the solid cured PDC material, to the first PDC ceramic, and combinations and variations of these. The dopant can also be added to, or be a part of, the binder that is used to form a shaped charged, e.g., a volumetric shape of SiC, for use as a source material in a vapor deposition process (e.g., PVT) to grow an SiC crystal. The preparation and use of shaped charge SiC source materials for vapor deposition (e.g., PVT) growth of SiC crystals, are disclosed and taught in US Pat. Publ. No. 2018/0290893, the entire disclosure of which is incorporated herein by reference.

In general, in embodiments of the present inventions, the dopant is preferably an integral part of the PDC material, the SiC source material and both. Thus, the dopant can be: (i) chemically bonded to the PDC material (e.g., part of the polymer chain in a liquid PDC material, part of the cured polymer in the solid cured PDC material or both); (ii) it can be held (chemically, mechanically, or both) within a matrix of the PDC material (e.g., a nano-composite), such as disclosed and taught in U.S. Pat. No. 10,633,400, the entire disclosure of which is incorporated herein by reference; (iii) it can be held (chemically, mechanically, or both) in the SiC source material; and (iv) combinations and variations of these.

Having the dopant, as an integral part of the SiC source material provides several benefits over the prior ways in which dopants were introduced into the crystal growing vapor deposition process. For example, having the dopant as an integral part of the SiC source material, allows for the dopant to be sublimed along with the Si and C from the source material to form the flux in the vapor deposition process and apparatus (e.g, PVT). In this manner the dopant is not separately added to the flux, after the flux is formed. Instead, the dopant is formed with, and as a part of the flux. Having the dopant in and as an integral part of flux formation provides greater control over the entire process, than by adding the dopant to the flux after the flux has formed, such as by a gas flow, or separate sublimation of a dopant. Thus, in general, preferred embodiments of the present inventions avoid the need to have a separate dopant source from the SiC source material. This would include avoiding the use of a dopant based gas flow into the vapor deposition apparatus, the use of a separate solid dopant source in the vapor deposition apparatus, and combinations of these. Although it is understood that in other embodiments a separate dopant based gas flow, for example with a second type of dopant, can be used.

In general, the location, distribution, and both, of the dopant (e.g., atomic impurity), within and throughout the SiC source material (e.g., a shaped charge source material), is fixed. Further, and preferably, the dopant remains fixed in that predetermined location and distribution, and preferably fixed throughout the majority of, and the entirety of, the vapor deposition process to grow the SiC crystal. In this manner, the dopant, can be uniformly distributed through the SiC source material. It can be varied by concentration, location and distribution, within the SiC source material, to take into account changes in flux formation and growth of the SiC crystal. In this latter manner, the predetermined placement of the dopant, is not uniform, but results in the uniform distribution of the dopant in the SiC crystal. In this manner, and in embodiments of the doped shaped charge source material, there is provided a matrix of Si, C and atomic impurities (e.g., donor atoms, acceptor atoms, or both). The doped shaped change is this a porous matrix of Si, C and the atomic impurities, where the matrix holds the atomic impurities, fixes the atomic impurities or both.

When using embodiments of a shaped charge SiC source material, the predetermined location and distribution of the dopant (e.g., atomic impurity), remains fixed in the solid source material, until the dopant is sublimed with the solid source. Thus, the dopant can remain fix in the solid source material, to the extent that this solid source material has yet to be sublimed, for at least 60%, 70%, 80%, 90% and 100% of the growth cycle of the crystal in the vapor deposition (e.g., PVT) process and apparatus. In other words, in these embodiments, the solid dopant does not shift its position in the shaped charged relative to the solid SiC during the growth cycle of the crystal.

Further, fixing the dopant (e.g., atomic impurity) in predetermined locations and distributions in the SiC source material (e.g., SiC shaped charge source material) provides the ability to obtain a high ratio of substitutional impurities to interstitial impurities in the SiC crystal (i.e, greater or more efficient use of the atomic impurity). This more efficient use of the atomic impurity reduces the adverse effects (e.g., stresses} that the interstitial impurities can cause in the SiC crystal. Because the SiC and the doping elements are co-sublimed as dopant atoms are revealed on the surface, the incorporation onto the growing boule is better assured at uniform concentrations throughout growth.

It is understood, that by having the dopant (e.g., atomic impurity) remaining “fixed” during the growth cycle of the crystal, is with respect to the unsublimed portion (i.e., the remaining yet to be sublimed portion) of that source material. As the source material is sublimed during the vapor deposition process, so is the dopant. In this manner the dopant forms in, and as a part of, the flux along with the Si and C based components of the flux. Further, in this manner, and preferably, the dopant is not separately added to the flux after the flux is formed. Instead, the dopant is an integral part of the flux and even an integral part of the flux formation.

In general, embodiments of the present invention relate to formulations and methods for providing a doped source material to make predetermined types of SiC wafers. In these embodiments the starting materials (e.g., precursors) are typically liquids that are then cured to a solid material. The solid starting material typically contain the dopant (e.g., atomic impurities). The solid starting material is then pyrolized into a ceramic, which contains the dopant. This ceramic is then further converted into SiC, which contains the dopant, and which forms the basis for the source material that is used for the growth of the predetermined type of SiC crystal, e.g., p-type, low resistivity p-type, and low resistivity n-type. Each of these predetermined crystal types are then manufactured into SiC wafers, e.g., p-type, low resistivity p-type and low resistivity n-type.

In general, preferred embodiments of the present inventions relate to formulations that use liquids containing Si, O and C to from a liquid precursor material, the liquid precursor material has one or more than one dopant (e.g., atomic impurity) added to it, and thus the liquid precursor material contains the dopant. The dopant, or dopants, are selected from elements and compounds that are intended to provide specific electrical, semiconductor or both properties to an SiC crystal and wafers that are eventually made from this liquid precursor material.

The dopants can be, or be based upon, any element that can form an electrically active atomic impurity in the SiC crystal and wafers, any element that provides one or more of a predetermined electrical, semiconductor or physical property to the SiC crystal and wafers. By way of example, dopants can be, or be based upon, elements selected from Group 13, IIIA (boron (B), aluminum (Al), et al.) of the periodic table, elements selected from Group 2 IIA (berylium (Be), et al.), and elements selected from Group 15 VA (nitrogen (N), phosphorous (P), arsenic (As), Antimony (Ab), et al.). Dopants may also be selected from elements in Group 16 VIA (e.g., oxygen (O), sulfur (S) et al.). Dopants may be selected from the transition metals, such as Ti, Cr, Mn, Ni, Fe, Co, etc. In embodiments, transition metal elements can add properties to the crystalline materials, and thus, to the doped SiC wafer, that provide for a new class of performance in devices such as spintronics, photonic band gaps, and electro chemical devices.

Preferred dopants form making p-type SiC crystals, ingots, boules and wafers are aluminum and boron. Preferred dopants for making n-type low resistivity wafers are phosphorous, nitrogen, and in some instances sulfur and a combination of phosphorous, sulfur and nitrogen.

Although this specification focusses on SiC vapor deposition technologies, and in particular SiC PVT technologies, it should be understood that the present inventions are not so limited, and can find applicability in other SiC crystalline growth processes, joining processes, as well as other applications.

Precursors & Source Materials—Generally

Embodiments of the present inventions preferably use, are based upon, or constitute PDCs that are “polysilocarb” materials, i.e., materials containing silicon (Si), oxygen (O) and carbon (C), and embodiments of such materials that have been cured, and embodiments of such materials that have been pyrolized, and embodiment of such materials that have been converted to SiC for use as source materials. Silicon oxycarbide materials, SiOC compositions, and similar such terms, unless specifically stated otherwise, refer to polysilocarb materials, and would include liquid materials, solid uncured materials, cured materials, ceramic materials, and combinations and variations of these. Polysilocarb materials and methods of making those materials are disclosed and taught in U.S. Pat. Nos. 9,815,943, 9,657,409, 10,322,936, 10,753,010, 11,014,819 and 11,091,370 and US Patent Publication No. 2018/0290893, the entire disclosures of each of which are incorporated herein by reference.

The polysilocarb materials may be of high and exceptionally high purity. Thus, they may be 99.99% pure, 99.999% pure and 99.9999% pure. The polysilocarb materials may also contain other elements. In particular, in preferred embodiments the polysilocarb materials contain dopants (e.g., atomic impurities). (The dopants are not counted as an impurity when making these percentage purity calculations, instead that are counted as part of SiC material for the purposes of making purity percentage calculations.) Polysilocarb materials are made from one or more polysilocarb precursor or precursor formulation. The polysilocarb precursor formulation contains one or more functionalized silicon polymers, or monomers, non-silicon based cross linkers, as well as, potentially other ingredients, such as for example, inhibitors, catalysts, dopants, and other additives. Dopants may include, for example, one or more than one of metals, metalloids, metal complexes, alloys, and non-metals, and combinations and variations of these.

Thus, for example p-type dopants may include, or be based upon one or more than one, of the elements selected from Group 13 (boron, et al). A particularly preferred dopant for making p-type SiC crystals, ingots, boules and wafers is aluminum.

For making low resistivity p-type crystals and wafers, the amount of dopant contained in the starting polysilocarb materials should be sufficient to carry forward in the process to provide enough dopant in the SiC source material to provide sufficient electrically active atomic impurities in the p-type crystalline material to have low resistivity. As used herein, unless specified otherwise “low resistivity” SiC p-type crystals, ingots, boules and wafers, have resistivities of 0.03 ohm-cm and less, of about 0.010 ohm-cm and less, of about 0.007 ohm-cm and less, of about 0.005 ohm-cm and less, of about 0.003 ohm-cm and less, from about 0.01 ohm-cm to about 0.001 ohm-cm, from about 0.009 ohm-cm to about 0.004 ohm-cm, and from about 0.006 ohm-cm to about 0.002 ohm-cm.

Preferred dopants for low resistivity n-type SiC crystalline materials are phosphorus, nitrogen, and sulfur (as a double donor) and combinations of these.

For making low resistivity n-type crystals and wafers, the amount of dopant contained in the starting polysilocarb materials should be sufficient to carry forward in the process to provide enough dopant in the SiC source material to provide sufficient electrically active atomic impurities in the n-type crystalline material to have low resistivity. As used herein, unless specified otherwise “low resistivity” SiC n-type crystals, ingots, boules and wafers, have resistivities of 0.03 ohm-cm and less, of about 0.010 ohm-cm and less, of about 0.007 ohm-cm and less, of about 0.005 ohm-cm and less, of about 0.003 ohm-cm and less, from about 0.01 ohm-cm to about 0.001 ohm-cm, from about 0.009 ohm-cm and about 0.004 ohm-cm, and from about 0.006 ohm-cm to about 0.002 ohm-cm.

In general, the polysilocarb precursor formulation is initially a liquid. The liquid precursors are cured to a solid or semi-solid SiOC (i.e., the “cured material”). The solid or semi-solid SiOC is then pyrolized to a ceramic SiOC, which is then converted (further pyrolysis) into SiC. These processes and transitions can take place in a single step, in separate or individual steps, and combinations and variations of these.

Precursor formulations that can be used as starting materials to which dopants (e.g., sources of donor, acceptor or both atoms) are added, and the methods to make those precursor formulations are disclosed and taught in U.S. Pat. No. 11,091,370, the entire disclosure of which is incorporated by reference. These formulations can provide carbon rich SiC source materials, and carbon deficient SiC source materials. Depending upon the type of donor or acceptor atoms, and other conditions, a predetermined stoichiometry (e.g., carbon rich, carbon deficient) in the source material can be beneficial, for example the predetermined stoichiometry can give rise to greater incorporation of the dopant as substitutional impurities in the SiC crystal.

The precursor formulations can be made from various precursors.

The precursor may be a siloxane backbone additive, such as, methyl hydrogen (MH), which formula is shown below.

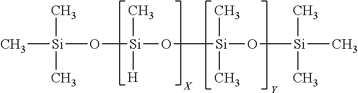

The MH may have a molecular weight (“mw” which can be measured as weight averaged molecular weight in amu or as g/mol) from about 400 mw to about 10,000 mw, from about 600 mw to about 3,000 mw, and may have a viscosity preferably from about 20 cps to about 60 cps. The percentage of methylsiloxane units “X” may be from 1% to 100%. The percentage of the dimethylsiloxane units “Y” may be from 0% to 99%. This precursor may be used to provide the backbone of the cross-linked structures, as well as, other features and characteristics to the cured preform and ceramic material. This precursor may also, among other things, be modified by reacting with unsaturated carbon compounds to produce new, or additional, precursors. Typically, methyl hydrogen fluid (MHF) has minimal amounts of “Y”, and more preferably “Y” is for all practical purposes zero.

The precursor may be vinyl substituted polydimethyl siloxane, which formula is shown below.

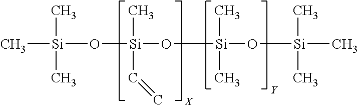

This precursor may have a molecular weight (mw) from about 400 mw to about 10,000 mw, and may have a viscosity preferably from about 50 cps to about 2,000 cps. The percentage of methylvinylsiloxane units “X” may be from 1% to 100%. The percentage of the dimethylsiloxane units “Y” may be from 0% to 99%. Preferably, X is about 100%. This precursor may be used to decrease cross-link density and improve toughness, as well as, other features and characteristics to the cured preform and ceramic material.

The precursor may be vinyl substituted and vinyl terminated polydimethyl siloxane, which formula is shown below.

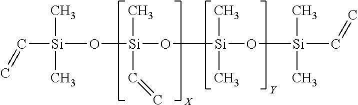

This precursor may have a molecular weight (mw) from about 500 mw to about 15,000 mw, and may preferably have a molecular weight from about 500 mw to 1,000 mw, and may have a viscosity preferably from about 10 cps to about 200 cps. The percentage of methylvinylsiloxane units “X” may be from 1% to 100%. The percentage of the dimethylsiloxane units “Y” may be from 0% to 99%. This precursor may be used to provide branching and decrease the cure temperature, as well as, other features and characteristics to the cured preform and ceramic material.

The precursor may be tetravinylcyclotetrasiloxane (“TV”), which formula is shown below.

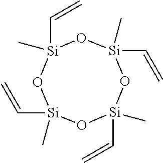 [SMILES: C=C[Si]1(C)O[Si](C)(C=C)O[Si](C)(C=C)O[Si](C)(C=C)O1]

The precursor may be a siloxane backbone additive, such as methyl terminated phenylethyl polysiloxane, (which may also be referred to as styrene vinyl benzene dimethyl polysiloxane), which formula is shown below.

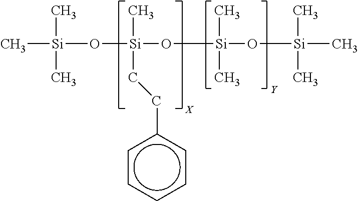

This precursor may have a molecular weight (mw) may be from about 800 mw to at least about 10,000 mw to at least about 20,000 mw, and may have a viscosity preferably from about 50 cps to about 350 cps. The percentage of styrene vinyl benzene siloxane units “X” may be from 1 to 60%. The percentage of the dimethylsiloxane units “Y” may be from 40% to 99%. This precursor may be used to provide improved toughness, decreases reaction cure exotherm, may change or alter the refractive index, adjust the refractive index of the polymer to match the refractive index of various types of glass, to provide for example transparent fiberglass, as well as, other features and characteristics to the cured preform and ceramic material.

The precursor may be divinylbenzene.

The precursors may also be any of the precursors and liquid starting materials disclosed and taught in U.S. Pat. No. 11,091,370.

Precursor formulations to which dopants (e.g., sources of donor, acceptor or both atoms) may be added to provide a doped SiC source material, include, for example, the following precursor formulations.

A precursor formulation made by mixing together 41 wt % linear methyl-hydrogen polysiloxane (MHF) and 59 wt % tetravinylcycloterasiloxane (TV).

A precursor formulation made by mixing together, at room temperature, 90% methyl terminated phenylethyl polysiloxane. (having 27% X) and 10% TV. This precursor formulation has 1.05 moles of hydride, 0.38 moles of vinyl, 0.26 moles of phenyl, and 1.17 moles of methyl. The precursor formulation has the following molar amounts of Si, C and O based upon 100 g of formulation.

| | | Molar Ratio of Si, C, O |
|---|---|---|
| | | (% of total moles in |
| | Moles | “Moles” Column) |
| Si | 1.17 | 20% |
| C | 3.47 | 60% |
| O | 1.17 | 20% |

As calculated, the SiOC derived from this formulation will have a calculated 2.31 moles of C after all CO has been removed, and has 98% excess C.

A precursor formulation made by mixing together at room temperature 70% methyl terminated phenylethyl polysiloxane (having 14% X) and 30% TV. This precursor formulation has 0.93 moles of hydride, 0.48 moles of vinyl, 0.13 moles of phenyl, and 1.28 moles of methyl. The precursor formulation has the following molar amounts of Si, C and O based upon 100 g of formulation.

| | | Molar Ratio of Si, C, O |
|---|---|---|
| | | (% of total moles in |
| | Moles | “Moles” Column) |
| Si | 1.28 | 23% |
| C | 3.05 | 54% |
| O | 1.28 | 23% |

As calculated, the SiOC derived from this formulation will have a calculated 1.77 moles of C after all CO has been removed, and has 38% excess C.

A precursor formulation made by mixing together at room temperature 50% methyl terminated phenylethyl polysiloxane (having 20% X) and 50% TV. This precursor formulation has 0.67 moles of hydride, 0.68 moles of vinyl, 0.10 moles of phenyl, and 1.25 moles of methyl. The precursor formulation has the following molar amounts of Si, C and O based upon 100 g of formulation.

| | | Molar Ratio of Si, C, O |
|---|---|---|
| | | (% of total moles in |
| | Moles | “Moles” Column) |
| Si | 1.25 | 22% |
| C | 3.18 | 56% |
| O | 1.25 | 22% |

As calculated, the SiOC derived from this formulation will have a calculated 1.93 moles of C after all CO has been removed, and has 55% excess C.

A precursor formulation made by mixing together at room temperature 65% methyl terminated phenylethyl polysiloxane (having 40% X) and 35% TV. This precursor formulation has 0.65 moles of hydride, 0.66 moles of vinyl, 0.25 moles of phenyl, and 1.06 moles of methyl. The precursor formulation has the following molar amounts of Si, C and O based upon 100 g of formulation.

| | | Molar Ratio of Si, C, O |
|---|---|---|
| | | (% of total moles in |
| | Moles | “Moles” Column) |
| Si | 1.06 | 18% |
| C | 3.87 | 54% |
| O | 1.06 | 28% |

As calculated, the SiOC derived from this formulation will have a calculated 2.81 moles of C after all CO has been removed, and has 166% excess C.

A precursor formulation made by mixing together at room temperature 65% MHF and 35% dicyclopentadiene (DCPD). This precursor formulation has 1.08 moles of hydride, 0.53 moles of vinyl, 0.0 moles of phenyl, and 1.08 moles of methyl. The precursor formulation has the following molar amounts of Si, C and O based upon 100 g of formulation.

| | | Molar Ratio of Si, C, O |
|---|---|---|
| | | (% of total moles in |
| | Moles | “Moles” Column) |
| Si | 1.08 | 18% |
| C | 3.73 | 64% |
| O | 1.08 | 18% |

As calculated, the SiOC derived from this formulation will have a calculated 2.65 moles of C after all CO has been removed, and has 144% excess C.

A precursor formulation made by mixing together at room temperature 82% MHF and 18% dicyclopentadiene (DCPD). This precursor formulation has 1.37 moles of hydride, 0.27 moles of vinyl, 0.0 moles of phenyl, and 1.37 moles of methyl. The precursor formulation has the following molar amounts of Si, C and O based upon 100 g of formulation.

| | | Molar Ratio of Si, C, O |
|---|---|---|
| | | (% of total moles in |
| | Moles | “Moles” Column) |
| Si | 1.37 | 25% |
| C | 2.73 | 50% |
| O | 1.37 | 25% |

As calculated, the SiOC derived from this formulation will have a calculated 1.37 moles of C after all CO has been removed, and has 0% excess C.

A precursor formulation made by mixing together at room temperature 46% MHF, 34% TV and 20% VT. This precursor formulation has 0.77 moles of hydride, 0.40 moles of vinyl, 0.0 moles of phenyl, and 1.43 moles of methyl. The precursor formulation has the following molar amounts of Si, C and O based upon 100 g of formulation.

| | | Molar Ratio of Si, C, O |
|---|---|---|
| | | (% of total moles in |
| | Moles | “Moles” Column) |
| Si | 1.43 | 30% |
| C | 1.95 | 40% |
| O | 1.43 | 30% |

As calculated, the SiOC derived from this formulation will have a calculated 0.53 moles of C after all CO has been removed, and has a 63% C deficit, or is 63% C starved.

A precursor formulation made by mixing together at room temperature 70% MHF, 20% TV and 10% VT. This precursor formulation has 1.17 moles of hydride, 0.23 moles of vinyl, 0.0 moles of phenyl, and 1.53 moles of methyl. The precursor formulation has the following molar amounts of Si, C and O based upon 100 g of formulation.

| | | Molar Ratio of Si, C, O |
|---|---|---|
| | | (% of total moles in |
| | Moles | “Moles” Column) |
| Si | 1.53 | 31% |
| C | 1.87 | 38% |
| O | 1.53 | 31% |

As calculated, the SiOC derived from this formulation will have a calculated 0.33 moles of C after all CO has been removed, and has a 78% C deficit, or is 78% C starved.

A precursor formulation having 50% methyl terminated phenylethyl polysiloxane (having 20% X) and 50% TV 95% MHF.

A precursor formulation having 54% methyl terminated phenylethyl polysiloxane (having 25% X) and 46% TV.

A precursor formulation having 57% methyl terminated phenylethyl polysiloxane (having 30% X) and 43% TV.

The precursor formulations may also be any of the precursor formulations disclose and taught in U.S. Pat. No. 11,091,370.

One or more dopant, (e.g., a composition or material that is based upon, or includes, the atomic impurities, to provide donor atoms or acceptor atoms in the flux during the crystal growth process) can be added to one or more of the liquid precursors, and thus added to the liquid precursor formulation, in which case the dopant will become a part of the cured SiOC material, and thus, the SiOC ceramic and the SiC. The dopant can be chemically reacted, i.e., chemically bonded to the components of the liquid precursors, in the liquid state. The dopant can be a part of a mixture, e.g., a solution or suspension, of the liquid polysilocarb precursors. In this situation, the dopant can be chemically bonded to the polysilocarb materials during the curing step and thus is chemically bonded to the cured SiOC material, the pyrolizing step and thus is chemically bonded to the ceramic SiOC material, or the conversation to SiC step and thus held (chemically or mechanically) in the doped SiC source material, and combinations and variations of these. This would be the case for either p-type doped SiC source material (which provides or grows a p-type crystal) or low resistivity type doped SiC source material (which provided or grows a low resistivity crystal either n-type or p-type).

The dopant can be part of a mixture, e.g., a solid mixed in with the cured material, the SiOC ceramic or both, in which case, the dopant can be chemically bonded to the SiOC materials, during one or more of the later steps to provide p-type doped SiC source material or low resistivity SiC source material.

In general, in embodiments of the present inventions, the dopant is preferably an integral part of the SiOC material, the SiC source material and both. Thus, the dopant can be: (i) chemically bonded to the SiOC material (e.g., part of the polymer chain, or composition of, one or more of the liquid SiOC precursor materials, part of the cured polymer in the cured SiOC material or both); (ii) it can be held (chemically, mechanically, or both) within a matrix of the SiOC material (e.g., a nano-composite), such as disclosed and taught in U.S. Pat. No. 10,633,400, the entire disclosure of which is incorporated herein by reference; (iii) it can be held (chemically, mechanically, or both) in the SiC source material; and (iv) combinations and variations of these.

In embodiments of the starting materials, intermediate materials and processes for providing p-type SiC material, the dopant is covalently bonded to one or more of the Si, C, O atoms in the SiOC composition. Thus, for example, converting the cured SiOC material to SiC, results in the dopant being covalently bonded to the Si, the C or both and being uniformly distributed throughout the SiC source material (i.e., powder), the SiC shaped charged (if one is used), for the vapor deposition process, e.g., PVT, to grow a p-type SiC crystal.

Typically, two types of reactions can be employed to covalently incorporate dopant molecules into the polymer network: hydrosilylation, and condensation reactions. In general, hydrosilylation reactions will employ a functional group of at least one alkene in the dopant molecule. Preferred embodiments, for example, would have two such functional groups, most preferably 3 to 4. Condensation reactions will employ an alkoxide, alcohol, or hydroxide group (—OR) where R is typically a small alkane or hydrogen.

In some embodiments, upon pyrolization, graphenic, graphitic, amorphous carbon structures and combinations and variations of these are present in the Si—O—C ceramic. A distribution of silicon species, consisting of SiOxCy structures, which result in SiO₄, SiO₃C, SiO₂C₂, SiOC₃, and SiC₄ are formed in varying ratios, arising from the precursor choice and their processing history. In these embodiments, the dopant, can be bound along with the amorphous carbon structures between neighboring carbon and a silicon atoms. In general, for SiOC, in the ceramic state, carbon is largely not coordinated to an oxygen atom, thus oxygen is largely coordinated to silicon, and the dopant would be largely coordinated to either silicon or carbon, depending upon its starting structure.

In a preferred embodiment, the starting material for the vapor deposition process, e.g., PVT, to grow a p-type crystal has a dopant selected from one or more of the elements from selected from Group 13 (Boron, et al) of the periodic table. The dopant is covalently bonded to the Si, the C or both of the source material, and is uniformly distributed thought out the source material. In a more preferred embodiment, the starting material is configured as a shaped charged, with the dopant distributed in a predetermined manner throughout the shaped charged, e.g., uniformly, layers of varied concentrations, etc. The vapor deposition process is then carried out using this source material, for example, as described in the subsection “Crystal Growth—Generally” of this Specification.

In preferred embodiments, the starting material for the vapor deposition process, e.g., PVT, to grow a low resistivity n-type crystal has a dopant selected from one or more of the elements from selected from Group 15 (Nitrogen, et al of the periodic table. The dopant is covalently bonded to the Si, the C or both of the source material, and is uniformly distributed thought out the source material. In a more preferred embodiment, the starting material is configured as a shaped charged, with the dopant distributed in a predetermined manner throughout the shaped charged, e.g., uniformly, layers of varied concentrations, etc. The vapor deposition process is then carried out using this source material, for example, as described in the subsection “Crystal Growth—Generally” of this Specification.

In an embodiment of the present p-type materials and processes, the dopant, acceptor impurity atoms are a part of the SiC source materials, e.g., chemically bonded, covalently bonded, or trapped within the SiC matrix. Further, in this embodiment, the dopant, and its acceptor impurity atoms, is not present in the form of an alloy in the starting material. For example, the dopant can be aluminum and the aluminum is present in the source material and is not present as an alloy. Thus, and in this manner, during vapor deposition, e.g., flux formation, and thereafter, the dopant, and the acceptor impurity atoms, is not an alloy, or is not otherwise formed into an alloy. It is believed that avoiding the use of an alloy, this alloying step, or alloy formation, provides significant advantages over the prior art, and provides for improved crystal growth, formation and properties. (As used herein an alloy is a substance composed of two or more metals or of a metal and a nonmetal intimately united usually by being fused together and dissolving in each other when molten. An alloy can have the different metals present in a ration of 99:1, 90:10, 80:20 to 50:50) The term alloy free, or without forming an alloy, would refer to not having, or forming, any alloys having a ratio 90:10, 80:20 to 50:50. In embodiments, alloys having a ratio of 99:1 to 91:9, may also be avoided, and thus not present in the starting materials, and not found or formed in the vapor deposition apparatus.

In an embodiment, the dopant can be a high purity aluminum/silicon alloy or aluminum-doped silicon powder as a precursor component. The doped silicon powder could be reacted carbon to form an Al-doped SiC powder. This powder can be made into a shaped charged source material.

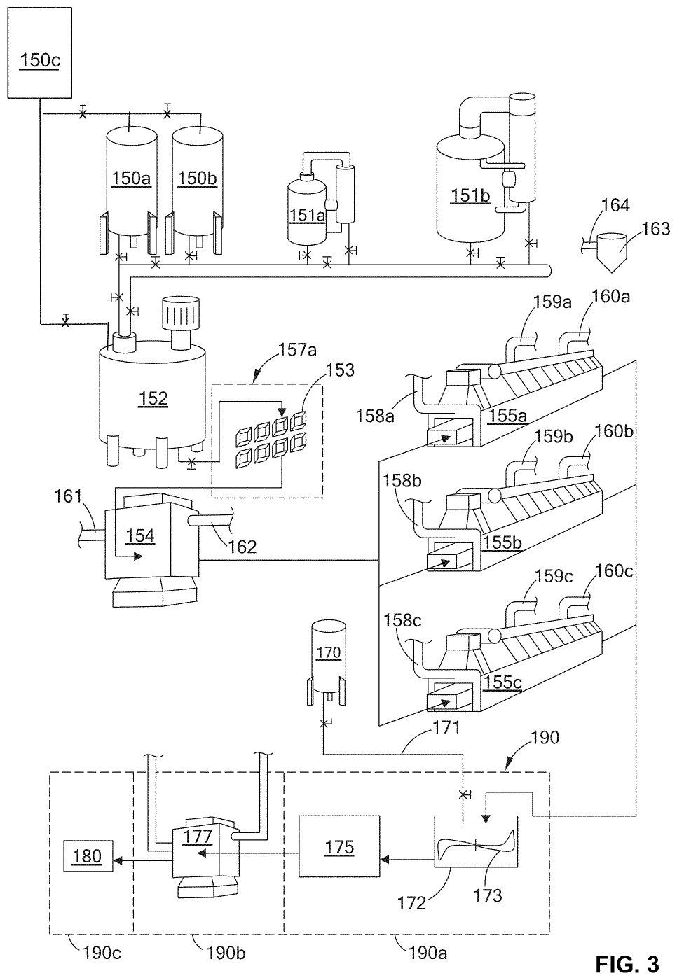

Turning to FIG. 3 there is provided a schematic perspective flow diagram of an embodiment of a system and method for making doped SiC source material, (p-type doped source material, low resistivity p-type doped source material, or low resistivity n-type source material) including shaped charges (e.g., volumetric shapes) of doped SiC source material. The SiC source materials is derived from doped SiOC precursors and intermediate materials. The doped SiC source materials and shaped charges preferably are of high purity (e.g., 3-nines, 4-nines, 5-nines and more, and preferably 6-nines or more). The lines, valves and interior surfaces of the system containing the precursors and other materials are made from or coated with materials that will not contaminate, e.g., provide a source of contaminants, to the SiOC, derived SiC and volumetric shapes of SiC.

In an embodiment where only p-type dopants (i.e., dopants providing a source of acceptor atoms) are being used, the presence of any materials that would be viewed as, or are a source of donor atoms, such as nitrogen, should be minimized, mitigated and eliminated. (It being noted that in other embodiments, nitrogen may be present in smaller amounts than the p-type dopant, and still obtain a p-type source material, i.e., configured to grow a crystal having a negative N_{C}.)

Similarly, in an embodiment were only n-type dopants (i.e., dopants providing a source of donor atoms) are being used, the presence of any materials that would be views as, or are a source of acceptor atoms, such as boron and aluminum, should be minimized, mitigated and eliminated. (It being noted that in other embodiments, boron or aluminum may be present in smaller amounts than the n-type dopant, and still obtain an n-type source material, i.e., configured to grow a crystal having a positive N_{C}.)

Storage tanks 150a, 150b hold liquid polysilocarb precursors and the dopant may be contained in a separate storage tank, hopper or bin 150c. If multiple dopants are used then multiple tanks, hoppers or bins, may also be present. The dopants can be added to the storage tanks or the mixer 152. In this embodiment one or both, or none, of the precursors can be taken through a distillation apparatus 151a and distillation apparatus 151b, to remove any contaminants from the liquid precursor. Care should be taken to not damage the dopant, or otherwise affect its properties.

The liquid precursors, and the dopant(s) are then transferred to a mixing vessel 152 where they are mixed to form a doped precursor batch (e.g., p-type, low resistivity p-type, or low resistivity n-type) and catalyzed. The precursor batch is then poured into vessels 153 (preferably in a clean room environment 157a) for placement in a furnace 154. The furnace 154 may have a sweep gas inlet 161 and off-gas take away line 162. Typically, the sweep gas is an inert gas, such as argon. The furnace cures the liquid polysilocarb material and reacts the dopant with the polysilocarb material to bond the dopant into, or as a part of the cured polysilocarb material.

The cured material, i.e., solid doped SiOC (e.g., p-type, low resistivity p-type, or low resistivity n-type), is then transferred, preferably under clean room conditions, to one and preferably several pyrolysis furnaces 155a, 155b, 155c, where it is transitioned from doped SiOC to doped SiC source material (e.g., p-type, low resistivity p-type, or low resistivity n-type). (It being noted that in this embodiment the SiOC ceramic will be a phase that is formed in the transition to SiC in the furnaces, e.g., 155a) The furnaces have sweep gas inlet lines 158a, 158b, 158c respectively, and two off-gas take away lines 159a and 160a, 159b and 160b, 159c and 160c respectively. Typically, the sweep gas is an inert gas, such as argon. The off-gasses can be processed, cleaned and starting materials recovered in the off-gas processing assembly 163 having an inlet line 164, which collects the off-gasses from various units in the system.

The resultant doped SiC source material (e.g., p-type, low resistivity p-type, or low resistivity n-type), which is a powder, is then transferred to a volumetric shape forming area 190, which preferably is under clean room conditions. In area 190 the doped SiC material is provided to a mixing vessel 172, having a mixing device 173 (e.g., blades, paddles, agitators, etc.). A binder, from binder tank 170, is added to the vessel 172, via line 171. In the mixing vessel 172 the SiC is mixed with the binder to form a slurry or blend. The consistency of the slurry should be such as to facilitate the later forming operation. The SiC-binder slurry is then transferred to a forming apparatus 175, where the slurry is formed into volumetric shapes, e.g., pellets, discs, blocks, etc., and preferably formed into a doped shaped charged source material (e.g., p-type, low resistivity p-type, or low resistivity n-type), and feed into oven 177, where the binder is cured to give the volumetric shape the desired strength and preferably pyrolized.

The volumetric shapes can also then be transferred to a packaging device 180, where they are packaged. Preferably these operations are performed under clean room conditions, and more preferable the operations are in separate clean rooms, or areas of a clean room, 190a, 190b, 190c. The shaped charges can also be directly provided to a vapor deposition apparatus (e.g., PVT) for growing a doped SiC crystal (e.g., p-type, low resistivity p-type, or low resistivity n-type).

Preferably, in making p-type doped SiC, low resistivity p-type doped or low resistivity n-type doped SiC source materials, in a preferred embodiment the polysilocarb precursors and the dopant, can be mixed at about 1 atmosphere, in cleaned air.

Preferably, in making SiC, and materials for use in making SiC, the curing of the doped, and preferably catalyzed, precursor materials takes place at temperatures in the range of from about 20° C. to about 150° C., from about 75° C. to about 125° C. and from about 80° C. to 90° C. and variations and combinations of these temperatures, as well as, all values within the ranges of these temperatures. The curing is conducted over a time period that preferably results in a hard cured material. The curing can take place in air or an inert atmosphere, and preferably the curing takes place in an argon atmosphere at ambient pressure. Preferably, for high purity materials, the furnace, containers, handling equipment, and other components of the curing apparatus are clean, essentially free from, and do not contribute any elements or materials, that would be considered impurities or contaminants, to the cured material. It being noted that in preferred embodiments a source of donor atoms or a source of acceptor atoms may be considered to be a contaminant, depending on the type of crystal being grown.

Preferably, in making doped SiC source materials (e.g., p-type, low resistivity p-type, or low resistivity n-type), the pyrolysis takes place at temperatures in the range of from about 800° C. to about 1300° C., from about 900° C. to about 1200° C. and from about 950° C. to 1150° C., as well as, all values within the range of these temperatures. The pyrolysis is conducted over a time period that preferably results in the complete pyrolysis of the cured doped SiOC material to the p-type doped SiC source material. Preferably the pyrolysis takes place in inert gas, e.g., argon, and more preferably in flowing argon gas at or about at atmospheric pressure. The gas can flow from about 1,200 cc/min to about 200 cc/min, from about 800 cc/min to about 400 cc/min, and at about 500 cc/min, as well as, all values within the range of these flows. Preferably, an initial vacuum evacuation of the processing furnace is completed to a reduced pressure at least below 1×10⁻³ Torr and re-pressurized to greater than or equal to 100 Torr with inert gas, e.g., Argon. More preferably, the vacuum evacuation is completed to a pressure below 1×10⁻⁵ Torr prior to re-pressurizing with inert gas. The vacuum evacuation process can be completed anywhere from zero to >4 times before proceeding. Preferably, for high purity materials, the furnace, containers, handling equipment, and other components of the curing apparatus are clean, essentially free from, free from and do not contribute any elements or materials, that would be considered contaminants, to the pyrolized material.

The pyrolysis may be conducted in any heating apparatus, that maintains the request temperature and environmental controls. Thus, for example pyrolysis may be done with, pressure furnaces, box furnaces, tube furnaces, crystal-growth furnaces, graphite box furnaces, arc melt furnaces, induction furnaces, kilns, MoSi₂ heating element furnaces, carbon furnaces, vacuum furnaces, gas fired furnaces, electric furnaces, direct heating, indirect heating, fluidized beds, RF furnaces, kilns, tunnel kilns, box kilns, shuttle kilns, coking type apparatus, lasers, microwaves, other electromagnetic radiation, and combinations and variations of these and other heating apparatus and systems that can obtain the request temperatures for pyrolysis.

Preferably, in making doped SiC source materials, the ceramic doped SiOC is converted to SiC in subsequent or continued pyrolysis or conversion steps. The conversion step from doped SiOC may be a part of, e.g., continuous with, the pyrolysis of the doped SiOC cured material, or it may be an entirely separate step in time, location and both. Depending upon the type of doped SiC desired the convention step (form SiOC to SiC) can be carried out from about 1,200° C. to about 2,550° C. and from about 1,300° C. to 1,700° C., as well as, all values within the range of these temperatures.

Generally, at temperatures from about 1,600° C. to 1900° C., the formation of beta types is favored over time. At temperatures above 1900° C., the formation of alpha types is favored over time. Preferably the conversion takes place in an inert gas, e.g., argon, and more preferably in flowing argon gas at or about at atmospheric pressure. The gas can flow from about 600 cc/min to about 10 cc/min, from about 300 cc/min to about 50 cc/min, and at about 80 cc/min to about 40 cc/min, as well as, all values within the range of these flows. Preferably, for high purity materials, the furnace, containers, handling equipment, and other components of the curing apparatus are clean, essentially free from, and do not contribute any elements or materials, that would be considered impurities or contaminants, to the SiC.

The subsequent yields for doped SiOC derived doped SiC are generally from about 10% to 50%, typically from 30% to 40%, although higher and lower ranges may be obtained, as well as, all values within the ranges of these percentages.

It is further understood that in deterring the amount of dopant to be present in the doped SiOC precursor materials, e.g., in mixer 152 or in cured solid SiOC, the loss of dopant throughout the entire process, including during crystal growth should be considered. Thus, sufficient dopant should be present in the SiC source material to reach the predetermined dopant levels, e.g., the predetermined amount of electrically active atoms in the crystal that is grown from that source material, and thus, the wafers that are made from that crystal, to provide the predetermined and intended electrical and semiconductor properties of the crystal and wafer.

The binders for forming the volumetric doped shaped source material, e.g., the doped shaped charge source material, may be any binder used to hold the SiC in the predetermined shape during processing, curing and later use of the volumetric shape. Embodiments of the binders can preferably be oxygen free. Embodiments of the binders can preferably be made up of materials having only carbon and hydrogen. Embodiments of the binder can be made from materials having oxygen. Embodiments of the binder can be any sintering aid used for sintering SiC. Embodiments of the binder can be molten silica. Embodiments of the binders can be polysilocarb precursor materials, including all of the liquid precursors set forth in this specification. Combinations and variations of these and other materials may also be used as binders. The binders can also contain a dopant, which can be the same or different dopant from the dopant in the SiC powder that is used to make the shape charged.

The binders can be cured, and pyrolized, to the extent required, under the conditions used for curing the polysilocarb precursors, or under the conditions needed to transform the binder into a hard (e.g., tough) enough material to maintain the shape of the volumetric shape. Thus, the curing, hardening, forming, or setting up, as the case may be, should be done based upon the characteristics of the binder.

Examples of embodiments of binders that have no oxygen would include polyethylene, silicon metal, hydrocarbon waxes, polystyrene, and polypropylene and combinations and variations of these.

Examples of embodiments of binders that contain only carbon and hydrogen would include polyethylene, hydrocarbon waxes, carbon or graphite powders, carbon black, HDPE, LDPE, UHDPE, and PP and combinations and variations of these.

Examples of embodiments of binders that contain oxygen would include boric acid, boron oxide, silicon dioxide, polyalcohols, polylactic acids, cellulosic materials, sugars and saccharides, polyesters, epoxies, siloxanes, silicates, silanes, silsesquioxanes, acetates such as ethylvinylacetate (EVA), polyacrylates such as PMMA, and polymer-derived ceramic precursors and combinations and variations of these.

Examples of embodiments of binders that are sintering aids would include silicon, boron oxide, boric acid, boron carbide, silicon and carbon powders, silica, silicates and polymer-derived ceramic precursors and combinations and variations of these.

The binder should be selected so as to not interfere with or otherwise inhibit the dopant, the growth of the doped SiC crystal, and the properties of the doped SiC crystal and wafers.

Embodiments of binders, would include the precursor formulations, both catalyzed and uncatalyzed, as disclosed and taught in US those materials are disclosed and taught in U.S. Pat. Nos. 9,815,943, 9,657,409, 10,322,936, 10,753,010, 11,014,819 and 11,091,370 and US Patent Publication No. 2018/0290893, the entire disclosures of each of which are incorporated herein by reference. Methods of curing these binders are disclosed and taught in these patents and published applications, the entire disclosure of each of which are incorporated herein by reference.

Ashbys catalyst, and others, can be largely unaffected by aluminum doped precursor formulations. Phosphorous containing precursor formulations may cause some catalyst inhibition. Catalyst inhibition from the dopant can be overcome by non-catalytic means (e.g., drive the reaction despite the absence of a catalyst) by for example compensating with more thermal energy during the cure process.

In a preferred embodiment, the doped volumetric shaped, e.g., shaped charge, source material (e.g., p-type, low resistivity p-type, or low resistivity n-type), are made using one or more of the polysilocarb precursor formulations disclosed and taught in the forgoing listed patents and published applications. The binder is pyrolized to SiC to provide a hard and durable doped shape charge source material. The dopant in this shaped charge source material is fixed.

In an embodiment, the binder is the same polysilocarb precursor, as sued to make the SiC source material, with or without dopant. Thus, the amount of dopant present in the binder can be from 0% to about 50%. The dopant in the binder may be used to adjust or fine tune the amount of dopant present in a particular doped SiC shaped charge source material.

It is understood, that although preferred, the doped SiC crystals and boules, can be grown without using a shaped charge, e.g., directly from a doped SiC polymer derived powder charge or starting material. Further, less desirable forms of SiC powder (e.g., not made from polymer derived ceramics) can be used to form a doped SiC shaped charge source material.

The ability to start with a doped liquid material, e.g., the precursor batch, having essentially all of the building blocks, e.g., Si and C and dopant, needed to make a doped SiC source material powder (e.g., not made from polymer derived ceramics) provides a significant advantage in controlling contamination, and in making predetermined rations of Si, C and dopant in the doped source material to control and effect flux formation and crystal growth in the PVT process and apparatus. It is also theorized, in part based upon the performance of the present polymer derived p-type doped SiC in vapor deposition apparatus and in growing p-type crystals, that the polymer derived SiC is different from non-polymer derived SiC, and the prior use of metal alloys, metal gasses, or both in crystal growth process. Thus, synergistic benefits in crystal growth and purity, wafer yield and device yield, further arise from one or more of the individual benefits of the polymer derved ceramic source materials, including, bulk density, particle size, phase of doped SiC (beta vs alpha), stoichiometry, oxygen content (very low to none, also lack of oxide layer), high (e.g., 99.999% pure) and ultra high (99.9999%) purity.

Dopant Materials—Generally

In general, the dopant can be any material, or combinations of materials, that can be used in, and does not interfere with, the PDC process, (e.g., polysilocarb based PDCs) for forming an SiC source material, and that provides the predetermined atomic impurities (e.g., donor atoms, acceptor atoms, and combinations of these) in the SiC source material, which material is then used in the vapor deposition process to produce a flux having these atomic impurities, and growing a crystal from that flux, with the crystal also having these atomic impurities as electrically active atomic impurities.

For p-type crystals, ingots, boules and wafers, and p-type low resistivity crystals, ingots, boules and wafers, aluminum and boron are the preferred atomic impurities, and thus preferred dopants are those materials that can provide these atomic impurities.

The dopant materials that, for example, provide aluminum in the source material, which can then provide aluminum atomic electrically active impurities into the SiC crystalline structure are generally: reactive aluminum materials; non-reactive aluminum materials; and pure alumina materials.

Typically, reactive aluminum materials are added to the liquid precursor materials (e.g., a precursor formulation) and then chemical react with those precursor materials during the curing step. Reactive aluminum materials, include for example:
(i) Aluminum alkoxide: Al(OR)₃ where R is an alkyl or phenyl group. The reaction with the polysilocarb precursor material is generally: 2Al(OR)₃+6SiH→2Al—(O—Si˜)₃+6 RH; (It should be noted that “—Si” and “Si—” as used in these reactions, represents the reactive Si functional group, that is attached to a larger structure such as a polymeric backbone, or ligand backbone, which larger structure is not shown in the reactions.)
(ii) Aluminum Hydroxide (R is Hydrogen). The reaction with the polysilocarb precursor material is generally: 2Al(OH)₃+6 SiH→2Al—(O—Si˜)₃+3H₂;
(iii) Bauxite, gibbsite, boehmite, diaspore. The reactions with the polysilocarb precursor material is generally: through the hydroxide functionality of these minerals, similar to (ii); and,
(iv) Trimethyl aluminum. The reaction with the polysilocarb precursor material is generally: 2(Al(Me)₃)+3H₂O→Al₂O₃+6CH₄.

Typically, non-reactive aluminum materials are added to the liquid precursor materials (e.g., “precursor formulation), but can be added to the cured material, the ceramic SiOC, the SiC source material and combinations and variations of these. The non-reactive materials are held by, or incorporated into, the SiOC and SiC ceramic materials during pyrolysis. Non-reactive materials include, for example aluminosilicate materials. Examples of such materials include: Mullite, kyanite, sillimanite, andalusite, Dumortierite and other Neosilicate powders; Kaolinite, Halloysite, and Pyrophyllite; Tectosilicates (feldspars); and, Zeolites.

Typically, pure alumina materials are added to the liquid precursor materials (e.g., precursor formulation), but can be added to the cured material, the ceramic SiOC, the SiC source material and combinations and variations of these. The pure alumina materials are held by, or incorporated into, the SiOC and SiC ceramic materials during pyrolysis. Pure alumina materials include, for example alumina powder Al₂O₃ and corundum (including sapphire, ruby, etc.)

All of the foregoing aluminum dopant materials provide aluminum in for example a ceramic oxide form in the SiC source material, and not as an alloy.

The dopant materials that, for example, provide boron in the source material, which can then provide boron atomic electrically active impurities into the SiC crystalline structure are generally: reactive boron materials; non-reactive boron materials

Typically, reactive boron materials are added to the liquid precursor materials (e.g., precursor formulation (1)) and then chemical react with those precursor materials during the curing step. Reactive boron materials, include for example:
(i) Boric acid B(OH)₃ The reaction with the polysilocarb precursor material is generally: 2B(OH)₃+6SiH→2B—(O—Si˜)₃+3H₂;
(ii) Borax (Na₂B₄O₇·10H₂O). The reaction with the SiOC precursor material is generally: a condensation reaction.
(iii) Boronic Adds R—B(OH)₂ where R is an alkene group such as a vinyl group. The reaction with the polysilocarb precursor material is generally: a condensation reaction; and,
(iv) Divinyl Borinic add Vi-B(OH)-Vi The reaction with the polysilocarb precursor material is generally: B-Vi+˜SiH→B—C—C—Si˜.

Typically, non-reactive boron materials are added to the liquid precursor materials (e.g., a precursor formulation), but can be added to the cured material, the ceramic SiOC, the SiC source material and combinations and variations of these. The non-reactive materials are held by, or incorporated into, the SiOC and SiC ceramic materials during pyrolysis. Non-reactive materials include, for example: Borosilicate glass; B₂O₃; Boron Carbide.

For n-type crystals, ingots, boules and wafers, and n-type low resistivity crystals, ingots, boules and wafers, nitrogen and phosphorous are the preferred atomic impurities, with phosphorous being a particularly preferred atomic impurity, and thus preferred dopants are those materials that can provide these atomic impurities.

Nitrogen containing or providing materials can be added to the liquid precursor materials (e.g., a precursor formulation). Such dopants would include amines; amides; azo & diazo; carbamates; urethanes; carboimides; heterocycles of C and N; ureas; isocyanates; as potential candidate functional groups to incorporate. Nylons or other N-containing carbon based polymers could also be added to the formulation to react during pyrolysis. However, it should be noted that the addition of too great an amount of nitrogen introduces undesirable stress, stacking faults and related defects to the crystals.

Typically, reactive phosphorus materials are added to the liquid precursor materials (e.g., a precursor formulation) and then chemical react with those precursor materials during the curing step. Reactive phosphorous materials, include for example:

(i) reactive oxides of P, such as (R)₃-Phosphine Oxides (R=alkyl group, phenyl group, styrenyl group), including Triphenylphosphine Oxide shown below

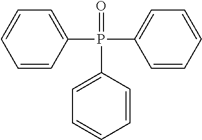 [SMILES: O=P(c1ccccc1)(c1ccccc1)c1ccccc1]

and phosphorus pentoxide, shown below.

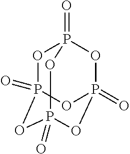 [SMILES: O=P12OP3(=O)OP(=O)(O1)OP(=O)(O2)O3]

The reaction with the polysilocarb precursor material with these dopants is generally

R₃—P═O*+˜Si—H→˜Si—O—P—R₃

(ii) reactive organic phosphines, such as (R1)ₙ—(R2)₃₋ₙ organophosphines (where R1=alkene group, styrenyl group, and R2=alkyl group, phenyl group) For example, Diphenylvinylphosphine, shown below

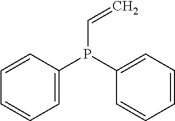

divinylphenylphosphine shown below

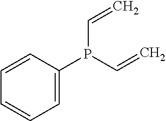

diphenylstyrenylphosphine shown below

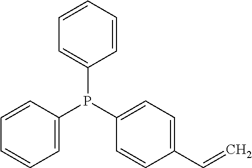 [SMILES: C=Cc1ccc(P(c2ccccc2)c2ccccc2)cc1]

triallylphosphine shown below, which is an example of material where n=3

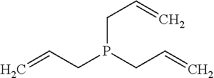

The reaction with the polysilocarb precursor material with these dopants is generally

R₃—P—C═C+˜Si—H→˜Si—C—C—P—R₃

(iii) phosphines, including PH₃, PCIS, PF₃, and PBr₃.
The reaction with the polysilocarb precursor material with these dopants is generally

PX₃+3˜SiH→P—(Si˜)₃+3HX where X is a halogen or Hydrogen

(iv) acids, including phosphoric acid (H₃PO₄); polyphosphoric acid (CAS #8017-16-1); Ammonium polyphosphate (CAS #68333-79-9); P(OR)₃ where R is any alkyl, or phenyl group, or hydrogen; O═P(OR)₃ where R is any alkyl or phenyl group, or hydrogen; tri-isopropyl phosphite, shown below

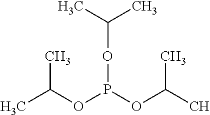

tri-isopropyl phosphate, shown below

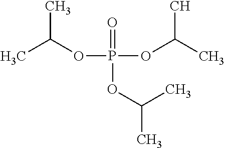

The reaction with the polysilocarb precursor material with these dopants is generally

2(OH)₃P═O+6˜Si—H→2(˜Si—O)₃—P═O+3H₂

Typically, non-reactive phosphorus materials are added to the liquid precursor materials (e.g., a precursor formulation), but can be added to the cured material, the ceramic SiOC, the SiC source material and combinations and variations of these. The non-reactive materials are held by, or incorporated into, the SiOC and SiC ceramic materials during pyrolysis. Non-reactive materials include, for example: phosphate compounds, such as shown below

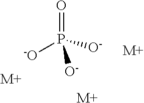

Where M+ is sodium, potassium, calcium, lithium, ammonium, etc.

phosphorus pentoxide, shown below

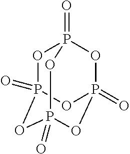 [SMILES: O=P12OP3(=O)OP(=O)(O1)OP(=O)(O2)O3]

phosphate minerals such as from the Apatite group (Ca₅(PO₄)₃R, where R is F, Cl, or OH),

Inorganic dopants containing both N and P may also be used. These are added to the liquid precursor materials (e.g., precursor formulation (1)), but can be added to the cured material, the ceramic SiOC, the SiC source material and combinations and variations of these. The inorganic materials are held by, or incorporated into, the SiOC and SiC ceramic materials during pyrolysis. These materials provide the ability to co-dope, providing both N and P from a single dopant source. Co-dopants include for example struvite ((NH₄)MgPO₄.8H₂0), phosphorous nitride group of materials, triphosphorous pentanitride (P₃N₅),

Other co-dopants (sources of N and P) are cyclophosphazene compounds, polyphosphazene compounds, and hexachlorotriphosphazene compounds. These co-dopants are added to the liquid precursor materials (e.g., a precursor formulation) and then chemical react with those precursor materials during the curing, pyrolysis or both steps.

Further, as previously noted, any of the forgoing dopants can be added to the binder being used to form a doped SiC shaped charge source material.

Dopants can be added to the precursor formulation, at weight percents of about 1%, about 2%, about 2.5%, about 5%, from 2% to about 10%, from about 1% to about 10%, less than 15%, less than 10%, less than 8%, and from about 2% to about 8%. Dopants can be added to the binder at weight percents of about 1%, from about 1% to about 10%, about 2%, about 2.5%, about 5%, from 2% to about 10%, less than 15%, less than 10%, and less than 8%, and from about 2% to about 8%.

There will be some loss of material during the curing step, and each pyrolysis step, e.g., yield losses. These yield losses will include the loss of dopant material. Thus, sufficient amounts of dopant should be added to take into account these yield losses, to provide the amount of dopant atoms required in the SiC source material for use in flux formation and crystal growth.

Doped Crystal Growth—Generally

Silicon carbide does not generally have a liquid phase, instead it sublimes, under vacuum, at temperatures above about 1,700 to 1,800° C. Typically, in industrial and commercial applications conditions are established so that the sublimation takes place at temperatures of about 2,500° C. and above. When silicon carbide sublimes it typically forms a vapor consisting of several different species of silicon and carbon. Generally, it is understood that the composition and form of the source material (e.g., shaped charged), temperature and pressure determine the ratio of the vapor phase components in the silicon carbon vapor.

The present inventions, among other things, provide for predetermining, preselecting and controlling the presence of dopants (e.g., additives, elements, compounds that are intended to provide a particular predetermined property to the SiC wafer) in the SiOC starting materials, that are then present in the SiC source materials, e.g., the powder for use in the vapor deposition crystal growth process.

When silicon carbide sublimes it typically forms a vapor consisting of various species of silicon and carbon, e.g., Si, C, SiC, Si₂C and SiC₂.

In general, the present inventions use PVT methods and apparatus, which are well understood and known to the art (e.g., U.S. Pat. No. 4,866,005 the entire disclosure of which is incorporated herein by reference) for the purpose of growing the present p-type crystals, low resistivity p-type crystals and low resistivity n-type crystals. During sublimation crystal growth, typically an elemental source consisting of silicon and carbon or SiC powder is sublimed to create a vapor flux of Si and C atoms which then condense on a seed crystal and eventually forming a larger crystal. In order to control the electrical properties (e.g., resisitivity/conductivity) of the SiC crystal impurity atoms are added into the vapor stream where they will incorporate into the crystal along with the silicon and carbon atoms. The incorporation of the impurities into the crystal is influenced by the seed temperature, pressure, seed face-silicon or carbon, and the carbon to silicon atom ratio in the vapor stream. The carbon to silicon ratio in the vapor stream is linked to the design of the source material, the temperature at the source and the pressure.

Silicon and aluminum are of similar atomic size and as a result the aluminum impurity atom will primarily locate at the silicon position in the crystal (as an electrically active atomic impurity), or at an interstitial position. To enhance the likelihood the aluminum atoms locate at a silicon site, a vapor stream with excess carbon is desired.

In typical sublimation growth of SiC, using prior non-PDC source materials, the vapor stream typically has more silicon than carbon. As a result, the aluminum atoms must compete with silicon atoms to occupy the silicon site. This characteristic of SiC sublimation growth based on inorganic sources such as silicon metal, graphite or SiC abrasive sources results in difficultly to incorporate sufficient aluminum in the crystal so that the conductivity of wafers cut from the crystal are useful for semiconductor device fabrication.

Embodiments of the present inventions, among other things, overcome this problem by having the ability to have source materials with excess carbon, as well as, having the dopant incorporated into and held by the source material. Thus, these doped PDC source materials can unexpectedly provide favorable flux conditions for high efficiency incorporation of p-type dopants in SiC crystals. This in turn enhances the electrical properties of the p-type crystal and enables the wafers cut form this crystal to be useful, of higher quality and superior electrical properties, and in particular commercially useful, for semiconductor device fabrication.

In embodiments there is an unexpected from the used of the PDC shaped charge source materials in that their ability to influence and control the Si/C ratio of the flux provides the ability to create a Si/C ratio that is more likely to enhance incorporation of p-type dopant atom impurities into the crystal when growing on the C-face of the crystal. While the Si/C ratio in flux at the seed can reduce over time, it does not likely drop below a value of 1, yet the enhancement of p-type dopant incorporation occurs. Thus, embodiments of the present shaped charge source materials provide the ability to grow p-type SiC crystals in PVT processes using C or Si face seed. In particular, p-type crystals can be grown on C or Si face, 4H or 6H seeds.

The preferred embodiments of boules are single crystal and have only a single polytype. It being understood, that embodiments of boules with multiple polytypes, with multiple crystals, and both, are also envisioned by the present specifications.

In an embodiment liquid PDC starting materials, preferably polysilocarb precursors, and more preferably liquid polysilocarb precursors have added to them or contain (e.g., chemically bonded, chemical complex, in solution, in the backbone of the polymer, in a mixture, etc.) a predetermined dopant, to provide a predetermined property to an SiC crystal.

While it is preferable to have the dopant present in the liquid starting materials, it may also be added to, e.g., combined or mixed with, the cured SiOC material, the ceramic SiOC material, and the shaped charge. In some situations, such as nitrogen, the dopant may also be added as a gas during the SiC crystal growth process.

The dopant can be a single material, e.g., element, or it can be two, three or more elements, typically selected from the same column in the period table. It is believed that the use of a combination of different materials from the same column in the period table (and thus having similar electron valance structures, but slightly different sizes) reduces the stresses in the SiC crystal. This in turn provides better, high quality, more useful, boules and wafers.

Preferred dopants for making p-type SiC crystals, boules and wafers are elements selected from Group 13 (boron et al) A preferred dopant for making p-type SiC crystals, boules and wafers is aluminum.

Preferred dopants for making n-type SiC crystals, boules and wafers are elements selected from Group 15 (nitrogen et al). Preferred dopants for making n-type SiC crystals, boules and wafers is nitrogen, phosphorous and combinations of these.

The use of phosphorous and a combination of nitrogen and phosphorous as the dopant (preferrable in the liquid polysilocarb starting materials) provides the ability to have low resistivity SiC wafers.

In less preferred embodiments of doped crystals (e.g., p-type, low resistivity p-type, low resistivity n-type), the dopant is not uniform over the length of the crystal. In this embodiment the concentration of dopant (as an electrically active atomic impurity) varies from seed bottom (side where growth of the crystal begins) to tail top side (side where growth ends), with this variation and can vary radially across the diameter of the crystal (as a percentage of maximum dopant concentration to minimum dopant concentration for the crystal) being in a range of about 300% to 5%.

In a preferred embodiment, the use of embodiments of the doped shaped charge source material, reduces these variation for both tail to seed (i.e., length or height of the crystal) and radially (across the diameter of the crystal), to about 100% to 5%, less than 200%, less than 150%, less than 100%, less than 50%, and less than 25%, and less than 105. This reduction in variation can further be obtained in a consistent manner, where the majority, and essentially all (i.e., greater than 90%) of the crystals grown in the PVT apparatus have the same lower variations.

In an embodiment a doped SiC crystal (e.g., p-type, low resistivity p-type, low resistivity n-type) has an essentially uniform distribution of the dopant throughout the crystal's structure, this is obtained by the use of predetermined doped shaped charge source material having the dopant distributed in the shape charge in a manner to provide for uniformity of the dopant incorporation into the crystal. Thus, the variation of dopant concentration or electrically active atom impurity concentration in embodiments of a, crystal, ingot, boule or wafer across the length (e.g., tail side to seed side (“top to bottom”)) and radially (as measured side to side moving along a diameter (“side to side”) is less than about 10%, less than about 5%, and less than about 2%, and less than 1%. Thus, the entirety of these crystalline materials exhibit the intended electrical properties and to the same degree (e.g., p-type electric behavior, p-type low resistivity electrical behavior, n-type low resistivity electrical behavior) and to the same degree. This permits the crystal, e.g., a boule, to be converted into SiC wafers, where the intended electric behavior is present throughout the entire wafer, and in particular throughout the thickness of the wafer. These materials, having the dopant or electrically active impurity essentially uniformly distributed (i.e., less than 10% variation, top to bottom, side to side as described above) throughout the materials will be referred to herein as a “uniform” or “uniformly” doped SiC wafer, ingot, crystal or boule.

Thus, in embodiments, a p-type SiC wafer does not have any layer of n-type material. Further, in a preferred embodiment this p-type SiC wafer (also the p-type crystal and the p-type boule) has the electorally active donor atoms distributed throughout the entire wafer (also the p-type crystal and the p-type boule), and in particular throughout the thickness of the wafer. Further, in a preferred embodiment this p-type SiC wafer (also the p-type crystal and the p-type boule) has the electrically active atomic impurity distributed throughout the entire wafer (also the p-type crystal and the p-type boule), and in particular throughout the thickness of the wafer. These materials, having the dopant or electrically active impurity essentially uniformly distributed (i.e., less than 10% variation, top to bottom, side to side, as described generally above) throughout the materials will be referred to herein as a “uniform p-type SiC” wafer, ingot, crystal or boule. These uniform p-type SiC crystals, ingot, boules, and wafers, also include p+ and p− types.

The low resistivity SiC wafers can be n-type and p-type. Preferably for the n-type low resistivity SiC wafer the dopant is phosphorous, or a mixture of phosphorous and nitrogen. Preferably, the dopants in the low resistivity crystal, ingot, boule and wafer are distributed throughout the crystal matrix, with a variation of less than 100%, less than 50%, less than 25%, and more preferably are uniform low resistivity SiC materials.

The present inventions provide embodiments of methods and processes for the growth of boules, e.g., vapor deposition of SiC to form a single crystal boule of p-type SiC or low resistivity p− or n− type SiC, that provides for very flat, e.g., having a limited amount of curvature or arc at the face of the boule. The very flat profile of the boule is achieved primarily by the use of preselected shapes of the SiC puck that is placed in the vapor deposition apparatus. The preselected shape, e.g., a shaped charge, is configured so that during the vapor deposition process the area of the flux, and the flow within that area, remains constant over the entirety of the boule growing process. In this manner the rate and amount of SiC that is deposited on the face of the boule as it is grow remains consistent and uniform during the boule growing process. Thus, for example in growing a 6 inch diameter boule the area of flux flow would be 28.27 inches² and the flow rate and amount of SiC flowing across that area would uniform across that entire area during the growth of the boule, e.g., a 3 inch length boule, a 4 inch length boule, etc. Even as the amount and location of the SiC that is available for sublimation changes, within the puck, during the process, the shape of the puck directs the flux, e.g., “directional flux,” in a manner to keep the flow of flux uniform across the area directly adjacent to the face of the boule. Shape charges and the use of charges for growing SiC crystals are disclosed and taught in US Patent Publ. No. 2018/0290893, the entire disclosure of which is incorporated herein by reference.

In an embodiment the flux is not maintained constant throughout the growth process. Thus, in this embodiment the rate, distribution of the flux across the growth face is managed, e.g., controlled in a predetermined manner, to provide predetermined growth of regions of the boule or growth face. Thus, for example, in the latter stages of growth the flux can be directed in a predetermined manner to compensate for the nonuniformity that has occurred in the boule's growth. In this example, areas where flux was greater in the earlier stages of growth have lesser flux in latter stages of growth; similarly, areas where flux was lesser in the earlier stages of growth have greater flux in latter stages of growth. In this way, the final boule growth face minimizes curvature, or maximizes the radius of curvature, of the boule face.

In an embodiment the use of controlled flux, and more preferably direction flux, can provide a 4 to 8 inch diameter p-type SiC or low resistivity SiC boule with a characteristic shape defined by a tail end having a positive radius of curvature when oriented above the seed end. The radius typically ranges 10 to 200 inches for SiC crystals with diameter 4-8 inches.

In embodiments the radius of curvature (i.e., the reciprocal of the curvature) of the tail can be at least about 6 inches, at least about 8 inches, at least about 20 inches, at least about 60 inches, and approaching infinite (i.e., planar), as well as all values within the range of these values. In an embodiment, of a 6 inch boule the radius of curvature (i.e., the reciprocal of the curvature) would be at least about 10 inches, at least about 15 inches, at least about 25 inches, at least about 60 inches, and approaching infinite (i.e., planar), as well as all values within the range of these values. In an embodiment the radius of curvature of the boule face is at least 2× the length of the boule, at least 5× the length of the boule, at least 10× the length of the boule, and at least 25× the length of the boule, up to and including where the boule face is planar, as well as all values in this range.

In an embodiment the flux can be manipulated with pressure, as well as, temperature, in addition to the composition and makeup of the PDC source material. For a given growth temperature, the growth can be slowed down by increasing the chamber pressure. The fastest rate is typically under “full” vacuum (e.g., vacuum pump is on and keeping the chamber pressure as low as possible). Thus, by way of example, to grow a boule at 400 μm/hr, the growth can be at a temp T1 under P1 of full vacuum, or could be at temp T2>T1 with a partial pressure of argon (P2>P1) of a few mBar to a few 10s of mBar. In this manner the flux and growth rate can be “tuned”.

In embodiments the polymer derived doped SiC imparts better polytype stability in the p-type SiC or low resistivity SiC boule due to a more consistent flux composition over time. This embodiment, i.e., controlled polytype stability, is valuable and important for boule manufacturers, as a polytype shift mid-growth means only a portion of the boule is the original polytype, which typically adversely impacts electronic properties which affect the device performance of the chips built therefrom.

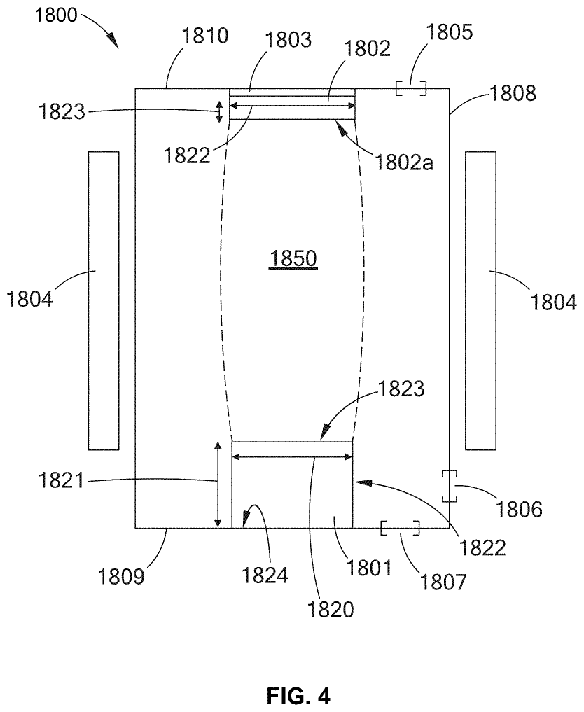

Turning to FIG. 4 there is shown a schematic cross sectional representation of an apparatus for growing p-type, or low resistivity p-type or n-type, SiC crystals and crystalline structures. Vapor deposition apparatus and processes, and in particular PVT apparatus and processes for using PDC SiC source materials are disclosed and taught in U.S. Pat. No. 10,753,010 and Publ. Pat. Appl. No. 2018/0290893, the entire disclosures of each of which are incorporated herein by reference. The vapor deposition device 1800 is a vessel having a side wall 1808, a bottom or bottom wall 1809, and a top or top wall 1810. The walls 1808, 1809, 1810 can have ports 1806, 1807, 1805, which can be openings, nozzles, values, that can control or permit the flow of gases into and out of the device 1800. The device 1800 has associated with it heating elements 1804. The heating elements can be configured and operated to provide a single temperature zone, or multiple temperature zones inside the device 1800. Inside of the device 1800 there is a shaped charge 1801 that is made out of doped SiC particles that have been formed together into a doped SiC volumetric shape (noting that in an embodiment the dopant may be incorporated into, or be a part of the binder used to make the SiC volumetric shape).

The shaped charge 1801 can have a predetermined porosity and density. The SiC particles can have a predetermined porosity and density. The SiC particles are held together, preferably by a binder. The shaped charge 1801 can be carbon rich, carbon starved, or stoichiometric. The shaped charge 1801 can have zones or layers that are carbon rich, carbon starved, or stoichiometric. Preferably, the SiC particles are SiOC polymer derived SiC. Non-polymer derived SiC may also be used as part or all of the shaped charge. The shaped charge 1801 has a height, shown by arrow 1821 and a cross section or diameter 1820. The shaped charge 1801 has an upper or top surface 1823 and a bottom surface 1824. In this embodiment the shaped charge 1801 is shown as a flat top and bottom cylinder; it being understood that any of the volumetric shapes contemplated by the present specification could be used in the device 1800.

At the top 1810 of the device 1800 there is a seed crystal 1802, the seed crystal may have the same type and amount of doping as intended to be found in the crystal that is grown on the seed crystal 1800. The see crystal 1800 has a surface 1802a. The seed crystal 1802 has a cross section or diameter 1822 and a height 1823. In some embodiments the seed crystal can be mounted on a movable platform 1803 to adjust the distance between surface 1802a and surface 1823.

The diameter 1820 of the shaped charge 1801 can be larger than, smaller than, or the same as the diameter 1822 of the seed crystal 1802.

In operation, the heating element 1804 raises the temperature of the shaped charge 1801 to the point where the SiC and dobant(s) sublimate. This sublimation causes the formation of a gas having the various species of silicon and carbon and dopant(s). This gas, i.e., the flux, is present in the area 1850 between surfaces 1802a and 1823. Depending upon the porosity, or other factors, the flux may also be present within the shaped charge 1801. The flux rises in the device 1800 through area 1850, where it deposits p-type SiC or n-type, or p-type low resistivity SiC, on surface 1802a. Surface 1802a must be kept at a temperature that is cool enough to cause the gaseous silicon carbon species and dopant atomic impurities to deposit out on its surface forming a doped SiC crystal. In this manner the seed crystal 1802 is grown into a p-type, or n-type or p-type low resistivity, SiC crystal by continuously adding grown SiC with dopant(s) in polytype-matched orientation onto its surface. Thus, unless adjusted by device 1803 (which is shown in the fully retracted position), during the growth of the boule, surface 1803 will grow toward the bottom 1809, and thus, decrease the distance between surface 1802a and the bottom 1809. The shape of the shaped charge can be used to create a predetermined temperature differential within the shaped charge during the vapor deposition process. This predetermined temperature differential can address, reduce and eliminate the detrimental effects of passivation, which is the condition where species build up in the shape charge during the process that reduces or prevents vapor formation.

In an embodiment were only p-type dopants are being used, the presence of any materials that would be viewed as, or are, are a source of donor atoms, such as nitrogen, should be minimized, mitigated and eliminated. (It being noted that in other embodiments, nitrogen may be present in smaller amounts than the p-type dopant, and still obtain a p-type source material, i.e., configured to grow a crystal having a negative Nc)

It is theorized that the process of sublimation and deposition takes place on the surface and inside of the volumetric shape, e.g., shaped charge, of the source material itself and follows the thermal gradient in the source material that naturally arises, or which thermal gradient may be determined by the shape of the volumetric shape. In an embodiment the binding material could preferably remain present and maintain the shape and integrity of the volumetric shape during sublimation temperatures, and thus, not sublime at or below the sublimation temperature of the SiC. This thermal gradient is typically from the exterior toward the interior and upward. It is theorized that material is continually sublimed and re-deposited on adjacent particles and in this way undergoes a refluxing or solid-state “fractional distillation” or “fractional sublimation” of the Si—C species, as well as the dopant.

It is further theorized that in an embodiment a volumetric shape and its predetermined gradient could allow some heavier impurities to be trapped behind in the bottom of the growth chamber within the structure of the volumetric shape, while the lighter elements are sublimed along with the Si—C vapor and are carried to the seed. This theoretically provides the ability to have dopants or other additives release at predetermined times in the process or growth cycle.

In an embodiment the shaped charge provides for a more consistent rate of flux formation for a given temperature. The shape of the shaped charge can be tailored to provide a more uniform temperature throughout the shape, allowing for a higher volume fraction of the shape to be subliming at once, driving higher rates of flux at the seed/vapor interface at a given temperature than a standard pile of powder or cylindrical shape of powder. Thus, growth of polytypes which require a lower temperature growth processes will not be limited to slower growth rates as a consequence.

Sublimation rate is measured in grams/hr. Flux is given by grams/cm²-hr (i.e., the rate of material passing through an area). Thus, a key area is the flux area corresponding to the instantaneous surface area of the boule growth surface, e.g., the face of the boule where SiC is being deposited. Typically, the flux area, and the area of the boule face are about the same, and these areas are typically slightly smaller than the cross sectional area of the growth chamber of the vapor deposition apparatus.

For the purpose of calculations and this analysis it is assumed, for ease of calculations, that the cross sectional area of the growth chamber is the same as the area of the flux and the area of the boule face. Thus, the growth rate (μm/hr) of the boule can be equated to the flux of vapor as well—μm/hr->g/hr (density of fully dense SiC is 3.21 g/cc) through the area of the boule surface (cm²). In-situ measurements can be done via X-ray imaging or X-ray computed tomography (CT). Otherwise, average growth rates can be determined by weighing the boule before/after growth.

Typical commercial growth rates are in the 200-500 μm/hr range. Embodiments of the present processes and volumetric shapes far exceed these existing commercial rates, while at the same time providing boules of equal and superior quality. For example, embodiments of the present inventions can have growth rates of about 550 to about 1,1000 μm/hr, about 800 to about 1,000 μm/hr, about 900 to about 1,100 μm/hr, about 700 μm/hr, about 800 μm/hr, about 900 μm/hr, about 1,000 μm/hr, 1,100 μm/hr at high temperatures and low pressure. Higher rates are contemplated and slower rates may also be used, as well as all rates within these ranges.

Generally, growth rates are driven by 1) temperature and 2) supplied gas pressure (Ar, N₂, etc). More gas pressure dilutes the vapor pressure of silicon carbon species at the seed, and face of the boule, and slows growth rate for any given temperature. Thus, pressure can be used to “dial-in” a growth rate.

Thus, embodiments of the volumetric shapes, e.g., the shaped charges, given a constant temperature, can maintain a consistent rate of flux production, e.g., constant, over the entire operation of p-type SiC or low resistivity, SiC crystal growth, including such crystals having about a 4 inch to about a 10 inch diameter, about 6 inch to about 8 inch diameter, about 4 inch diameter, about 6 inch diameter, about 8 inch diameter and larger and smaller, as well as all diameters within the range of these values. Embodiments of the volumetric shapes, given a constant temperature for the entire p-type SiC or low resistivity SiC crystal growth process, can maintain the rate of flux production, and thus the rate of boule growth at a constant rate, a constant rate, at a rate that has less than about 0.001% change, at a rate that has less than about 0.01% change, at a rate that has less than about 1% change, at a rate that has less than about 5% change, at a rate that has less than about 20% change, at rate that has from about 0.001% change to about 15% change, at rate that has from about 0.01% change to about 5% change, and combinations and variations of these during the growth of the crystal, as well as all values within the range of these values. In embodiments, at constant temperature, the rate of flux formation remains: at about a 99.999% to about a 60% of its maximum rate; at about a 99% to about a 95% of its maximum rate; at about a 99.99% to about a 80% of its maximum rate; at about a 99% to about a 70% of its maximum rate; at about a 95% to about a 70% of its maximum rate; at about 99% to about 95% of its maximum rate; and combinations and variations of these during the growth of the boule, as well as, all values within the range of these percentages.

Embodiments provide for the distribution of different stoichiometry, binder content, dopant content and both of powder throughout the shape, e.g., layers, zones, areas having different types of powder starting material, different binders, and combinations and variations of these. This predetermined distribution of different stoichiometries, binder content and both provide several advantages, including: customization of the sublimation composition as the source material is consumed from the outside in, which enables less shift in composition from beginning to end of the growth cycle. This predetermined distribution of different stoichiometries, binder content and both can also enhance polytype stability because of the consistent composition of the vapor.

Embodiments of the present inventions include the use of doped SiC in making p-type SiC or low resistivity SiC wafers for applications in electronics and semiconductor applications. In both the vapor deposition apparatus and processes to create the p-type SiC or low resistivity SiC crystals and p-type SiC or low resistivity SiC wafers for later use, doped (and preferably high purity) SiC is required.

Embodiment of the present polysilocarb p-type SiC or low resistivity SiC, and the p-type SiC or low resistivity SiC boules, p-type SiC or low resistivity SiC wafers and other structures that are made from the polysilocarb derived SiC, exhibit polymorphism, and generally a one dimensional polymorphism referred to as polytypism. Thus, polysilocarb derived p-type SiC or low resistivity SiC can be present in many, theoretically infinite, different polytypes. As used herein, unless expressly provided otherwise, the term polytypism, polytypes and similar such terms should be given their broadest possible meaning, and would include the various different frames, structures, or arrangements by which silicon carbide tetrahedrons (SiC₄) are configured. Generally, these polytypes fall into two categories—alpha (α) and beta (β).

Embodiments of the alpha category of polysilocarb derived p-type SiC or low resistivity SiC typically contains hexagonal (H), rhombohedral (R), trigonal (T) structures and may contain combinations of these. The beta category typically contains a cubic (C) or zincblende structure. Thus, for example, polytypes of polysilocarb derived p-type SiC or low resistivity SiC would include: 3C—SiC (β-SiC or β3C—SiC), which has a stacking sequence of ABCABC . . . ; 2H—SiC, which has a stacking sequence of ABAB . . . ; 4H—SiC, which has a stacking sequence of ABCBABCB . . . ; and 6H—SiC (a common form of alpha silicon carbide, α 6H—SiC), which has a stacking sequence of ABCACBABCACB . . . . Examples, of other forms of alpha silicon carbide would include 8H, 10H, 16H, 18H, 19H, 15R, 21R, 24H, 33R, 39R, 27R, 48H, and 51R.

Embodiments of polysilocarb derived p-type SiC or low resistivity SiC may be polycrystalline or single (mono-) crystalline. Generally, in polycrystalline materials there are present grain boundaries as the interface between two grains, or crystallites of the materials. These grain boundaries can be between the same polytype having different orientations, or between different polytypes, having the same or different orientations, and combinations and variations of these. Mono-crystalline structures are made up of a single polytype and have essentially no grain boundaries. In a preferred embodiment, the p-type SiC or low resistivity SiC are mon-crystalline.

Embodiments of the present methods result in boules, preferable single crystal p-type SiC or low resistivity SiC boules. These boules can have lengths from about ½ inch to about 5 inches, about ½ inch to about 3 inches, about 1 inch to about 2 inches, greater than about ½ inch, greater than about 1 inch and greater than about 2 inches. Larger and smaller sizes, as well as, all values within the range of these sizes, are contemplated. The boules can have cross sections, e.g., diameters, of from about ½ inch to about 9 inches, from about 2 inches to about 8 inches, from about 1 inch to about 6 inches, greater than about 1 inch, greater than about 2 inches, greater than about 4 inches, about 4 inches, about 6 inches and about 8 inches about 12 inches and about 18 inches. Other sizes, as well as, all values within the range of these sizes, are contemplated.

P- and Low Resistivity Type Wafers—Generally

In general, the process for making electronic components from p-type SiC or low resistivity SiC boules involves cutting the p-type SiC or low resistivity SiC SiC single crystalline boule into a thin wafer. The SiC wafers produced are the starting point for fabrication of SiC based semiconductor devices. SEMI (www.semi.org) has developed and published standards for the specification of SiC wafers of various diameters up to 150 mm. These standards are well known and understood by those of skill in the art. Due to the prior limitations of the SiC industry to commercialize p-type SiC crystals and wafers, and only commercialize n-type, nitrogen doped SiC crystals and wafers, the best-known methods for fabricating SiC wafers suitable for use in manufacturing semiconductor device are based on SiC n-type wafers, and can be used for the fabrication of p-type, n-type low resistivity, and p-type low resistivity wafers.

Embodiments of the doped wafers of the present inventions have the diameter of the boule, from which they were cut, and typically have a thickness of about 100 μm to about 500 μm. Preferably, the p-type electric properties or the low resistivity properties are distributed throughout the entire length of the boule or the entire thickness of the wafer. More preferably, the p-type electric properties or the low resistivity properties are uniformly distributed throughout the entire length of the boule or the entire thickness of the wafer. The p-type SiC or low resistivity SiC wafers are then polished, on one or both sides. The polished wafers are then used as substrates for the fabricated of microelectronic semiconductor devices. Thus, the p-type SiC or low resistivity SiC wafer serves as a substrate for microelectronic devices that are built on the wafer. The fabrication of these microelectronic devices includes microfabrication processing steps, such as, epitaxial growth, doping or ion implantation, etching, deposition of various materials, and photolithographic patterning, to name a few. Once fabricated from the p-type SiC or low resistivity SiC wafer, the wafer, and thus the individual microcircuits, is separated, in a process know as dicing, into individual semiconductors devices. These devices are then used in the making of, e.g., incorporated into, various larger semiconductor and electronic devices.

Embodiments of the present methods and resultant p-type SiC or low resistivity SiC wafers include, among others, about 2-inch diameter wafers and smaller, about 3-inch diameter wafers, about 4-inch diameter wafers, about 5-inch diameter wafers, about 6-inch diameter wafers, about 7-inch diameter wafers, about 12-inch diameter wafers and potentially larger, wafers having diameters from about 2 inches to about 8 inches, wafers having diameters from about 4 inches to about 6 inches, square shaped, round shaped, and other shapes, surface area per side of about 1 square inch, about 4 square inches, about 8 square inches, about 10 square inches, about 12 square inches, about 30 square inches, about 50 square inches, and larger and smaller, a thickness of about 100 μm, a thickness of about 200 μm, a thickness of about 300 μm, a thickness of about 500 μm, a thickness of about 700 μm, a thickness from about 50 μm to about 800 μm, a thickness from about 100 μm to about 700 μm, a thickness from about 100 μm to about 400 μm, a thickness from about 100 μm to about 300 μm, a thickness from about 100 μm to about 200 μm and larger and smaller thickness, and combinations and variations of these, as well as, all values within the range of these dimensions.

Embodiments of the present methods and resultant cut and polished p-type SiC or low resistivity SiC wafers may also include being used to initiate the growth of a boule, (i.e., as the “seed”) from which the rest of the grown boule matches the structure. The p-type SiC or low resistivity SiC wafer, or p-type SiC or low resistivity SiC seed, can be, among others, about 2-inch diameter wafers and smaller, about 3-inch diameter wafers, about 4-inch diameter wafers, about 5-inch diameter wafers, about 6-inch diameter wafers, about 7-inch diameter wafers, about 12-inch diameter wafers and potentially larger, wafers having diameters from about 2 inches to about 8 inches, wafers having diameters from about 4 inches to about 6 inches, square shaped, round shaped, and other shapes, surface area per side of about 4 square inches, about 8 square inches, about 12 square inches, about 30 square inches, about 50 square inches, and larger and smaller, a thickness of about 100 μm, a thickness of about 200 μm, a thickness of about 300 μm, a thickness of about 500 μm, a thickness of about 1500 μm, a thickness of about 2500 μm, a thickness from about 50 μm to about 2000 μm, a thickness from about 500 μm to about 1800 μm, a thickness from about 800 μm to about 1500 μm, a thickness from about 500 μm to about 1200 μm, a thickness from about 200 μm to about 2000 μm, a thickness from about 50 μm to about 2500 μm, and larger and smaller thickness, and combinations and variations of these, as well as, all values within the range of these dimensions.

Embodiments of the present p-type SiC or low resistivity SiC boules, p-type SiC or low resistivity SiC wafers, and the microelectronics fabricated from those wafers, find applications and utilizations in among other things, diodes, broad band amplifiers, military communications, radar, telecom, data link and tactical data links, satcom and point-to-point radio power electronics, LEDs, lasers, lighting and sensors. Additionally, these embodiments can find applications and uses in transistors, such High-electron-mobility transisitors (HEMT), including HEMT-based monolithic microwave integrated circuit (MMIC) and IGBTs. These transistors can employ a distributed (traveling-wave) amplifier design approach, and with SiC's greater band gap, enabling extremely wide bandwidths to be achieved in a small footprint. Thus, embodiments of the present inventions would include these devices and articles that are made from or otherwise based upon the present methods, vapor deposition techniques, and polymer derived SiC, SiC boules, SiC wafers and the microelectronics fabricated from these wafers.

Embodiments of polysilocarb derived p-type SiC or low resistivity SiC SiC, in particular high purity SiC, have many unique properties that, among other things, make them advantageous and desirable for use in the electronics, solar, and power transmission industries and applications. They can function as a p-type or low resistivity semiconductor material that is very stable, and suitable for several demanding applications, including high power, high-frequency, high-temperature, and corrosive environments and uses. Polymer derived p-type SiC or low resistivity SiC is a very hard material with a Young's modulus of 424 GPa.

In an embodiment, if dopants are required to be added to the material, they can be added by way of the precursor and thus be present in a controlled manner and amount for growth into a boule, or other structure. Embodiments of precursor formulations may have dopant, or complexes that carry and bind the dopant into the ceramic and then the converted SiC, so that upon vapor deposition process the dopant is available and in a usable form.

Additionally, dopants or other additives to provide custom or predetermined properties to wafers, layers and structures that are made from embodiments of the polymer derived SiC. In these embodiments, such property enhancing additives would not be considered impurities, as they are intended to be in, necessary to have in, the end product. The property enhancing additives can be incorporated into the liquid precursor materials. Depending on the nature of the property enhancing additive, it may be a part of the precursor back bone, it may be complexed, or part of a complex, to incorporate it into the liquid precursors, or it can be present in other forms that will enable it to survive (e.g., be in a form that lets it function as intended in the final material). The property enhancing additive can also be added as a coating to the SiC or SiOC powdered material, can be added as a vapor or gas during processing, or can be in powder form and mixed with the polymer derived SiC or SiOC particles, to name a few. In an embodiment the property enhancing additive comprises or is a part of the binder for the volumetric shape. In an embodiment the property enhancing additive can be a coating on the volumetric shape. Further, the form and manner in which the property enhancing additive is present, should preferably be such that it has minimal, and more preferably, no adverse effect on processing conditions, processing time, and quality of the end products.

P-Type Devices—Generally

These p-type SiC wafers, provides the ability to manufacture circuits, semiconductor devices, and chips that were previously designed with Silicon p-type wafers, and to do so with minimal need to rewrite or rework the circuit or chip design. Thus, in an embodiment there is provided the direct building of a circuit or device designed using a p-type silicon substrate, and instead using a device made with an SiC p-type wafer, without the need to modify, or configure or adapt the circuit based on silicon devices.

In this manner, embodiments of the present invention addresses the gap power circuit designers faced in taking advantage of the full range of benefits from using SiC devices by providing a manufacturable method to produce 4H—SiC or 6H—SiC p-type substrates (e.g., wafers) with low defects, resistivity properties and substrate diameter consistent with current requirements to manufacture devices, such as: Schottky barrier diodes (SBD), junction barrier Schottky diodes (JBS), and MOSFETS, as well as, transistors, such as gate-turn off transistors (GTOs) and integrated gate bipolar transistors (IGBTs), and variants and other types of these transistors and devices. Embodiments of the present inventions enable manufacture of p-type substrates with diameter and resistivity matching, and preferably exceeding, what is produced commercially today from n-type SiC crystals. The p-type wafers disclosed and taught herein provide the capability to, and thus enable, device manufacturers to extend the utility of SiC to all voltage range, and amperage range devices made today with n-type SiC to p-type SiC. Based upon the p-type wafers disclosed and thought herein, designers of power circuits will now be able to extend the benefits of SiC devices to all power management applications for all voltage range, voltage polarity, and amperage circuit designs, among others.

The embodiments of the present inventions can have, or utilize, one or more of the embodiments, features, functions, parameters, components, processes or systems set forth in the Precursors & Source Materials—Generally, Dopant Materials—Generally, Doped Crystal Growth—Generally, P- and Low Resistivity Type Wafers—Generally, and P-Type Devices—Generally teachings of this Specification, as well as, one or more of the embodiments, features, functions, parameters, components, processes or systems in the examples and figures.

### EXAMPLES

The following examples are provided to illustrate various embodiments of systems, processes, compositions, applications and materials of the present inventions. These examples are for illustrative purposes, may be prophetic, and should not be viewed as, and do not otherwise limit the scope of the present inventions. The percentages used in the examples, unless expressly provided otherwise, are weight percents of the total, e.g., formulation, mixture, product, or structure. The usage X/Y or XY indicates % of X and the % of Y in the formulation, unless expressly provided otherwise. The usage X/Y/Z or XYZ indicates the % of X, % of Y and % of Z in the formulation, unless expressly provided otherwise.

### Example 1

In an embodiment a dispersion of 2.5 wt % of 5 μm mullite powder (MU-101, Micron Metals) is added to a precursor formulation of 41% MHF 59% TV formulation with 30 ppb of Pt as Ashbys catalyst. The doped precursor formulation is cured, then pyrolized to SiC. The SiC powered is then made into a shaped charge by using the doped precursor formulation as the shaped charge binder, molding into shape, and then curing said shape into a green body. The green body is pyrolyzed and converted to a doped SiC shaped charge source material. Further details are set forth in Examples 1A to 1D.

### Example 1A

Liquid Al doped precursor formulations, as set forth in Table 1, for use in making a p-type SiC source material for use in growing a p-type SiC crystal.

TABLE 1

| | Precursor | Mullite | total weight | Weight | |
|---|---|---|---|---|---|
| Liquid | formulation* | weight | before cure | after cure | Cure |
| Batch | weight (g) | (g) | (g) | (g) | yield |
| 1 | 2043.6 | 51.090 | 2094.7 | 2042.6 | 97.5% |
| 2 | 2042.4 | 51.080 | 2093.5 | 2045.8 | 97.7% |
| 3 | 2051.9 | 51.395 | 2103.3 | 2032.1 | 96.6% |
| 4 | 2046.3 | 51.109 | 2097.4 | 2044.9 | 97.5% |
| 5 | 2036.2 | 50.987 | 2087.2 | 2031.9 | 97.4% |

Target for ratio by weight of Mullite to precursor formulation weight is 2.5% *41 wt % linear methyl-hydrogen polysiloxane (MHF) and 59 wt % tetravinylcycloterasiloxane (TV).

### Example 1B

The cured Al doped precursor formulations from Example 1A are pyrolized to provide an Al doped SiC materials, as set forth in Table 2.

TABLE 2

| Cured | Material weight | Material weight | |
|---|---|---|---|
| Batch | before run (g) | after run (g) | Yield |
| 1 | 2844.0 | 1016.3 | 35.7% |
| 2 | 2406.0 | 831.5 | 34.6% |
| 3 | 3113.2 | 1042.5 | 33.5% |

### Example 1C

The ceramic Al doped SiC materials from Example 1B are formed into a volumetric shape and cured, as shown in Table 3. Mullite is added with the binder in forming the volumetric shape.

TABLE 3

| | Weight of | Binder and | Weight of Al | | | |
|---|---|---|---|---|---|---|
| | Mullite | Mullite, | doped SiC | Weight of | Weight of | |
| Weight of | added to | combined | Powder | Shape Before | Shape After | Cure |
| binder* (g) | binder (g) | weight (g) | Used (g) | Cure (g) | Cure (g) | Yield |
| 421.2 | 10.8 | 432 | 2880 | 3312 | 3264.9 | 98.58% |

*41 wt % linear methyl-hydrogen polysiloxane (MHF) and 59 wt % tetravinylcycloterasiloxane (TV)

### Example 1D

The cured volumetric shape of Example 1C is pyrolized, as set forth in Table 4, to provide an Al doped SiC shape charge source material, for use in PVT growth of a p-type SiC crystal.

TABLE 4

| Before pyrolysis | After pyrolysis | |
|---|---|---|
| Weight (g) | Weight (g) | Yield |
| 3264.9 | 2925.4 | 89.60% |

### Example 2

The same general formulations and procedures of Examples 1A to 1D are followed, except instead of aluminum dopants, triallylphosphine is added to the liquid pressor formulation (1% to 15% by weight triallylphosphine to precursor formulation) and may also be added with the binder (1% to 15% by weight triallylphosphine to the P doped SiC powder and binder) to form the cured P doped SiC volumetric shape, which is then pyrolized to form the P doped SiC shaped charge source material. The P doped SiC shaped charge source material is for use in PVT growth of a low resistivity n-type SiC crystal.

### Example 3

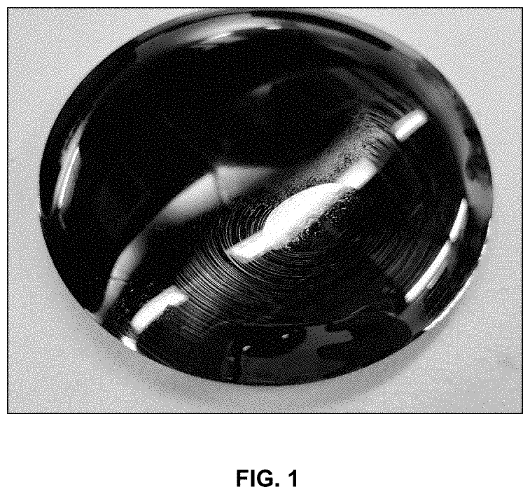

Turning to FIG. 1 there shown a photograph of a p-type SiC crystal having a diameter of about 150 mm. The crystal was grown using a PVT process and apparatus and using an Al doped SiC shaped charge source material of the type in Example 1D. The p-type crystal has 70 ppm Al. The p-type crystal has 5.5×10¹⁸ Al atoms/cc. The crystal has a length of about 23 mm. A thin slice of the crystal was prepared and polished and was Blue/purple in color when viewed in transmission. No evidence of polytype switching from 4H to another polytype was observed.

### Example 4

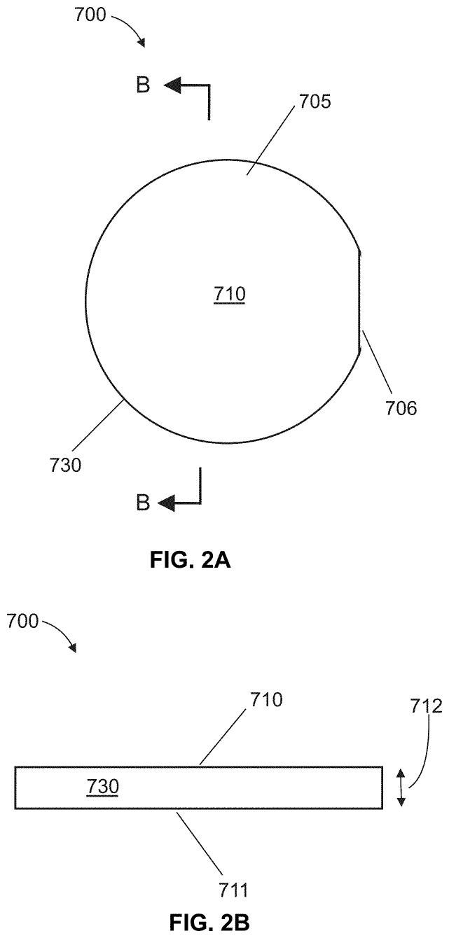

Turning to FIG. 2A there is shown a plan view schematic of a doped SiC wafer 700. FIG. 2B is a cross sectional view of the wafer 700 along line B-B. The wafer 700 can be a p-type SiC wafer, the wafer 700 can be low resistivity p-type SiC wafer, or the wafer 700 can be a low resistivity n-type SiC wafer. The wafer 700 is a disc like crystalline structure that is semicircular in shape 705, having a flat 706. It being understood that the wafer may be circular, or may have more than one flat. The wafer 700 has an edge 730. The wafer 700 has a top or top surface 710, a bottom or bottom surface 711 and a thickness shown by arrow 712. Both the top and bottom surfaces, as well as, the entire thickness 712 of the wafer 700 are doped SiC crystal. It being understood that one surface is typical the C face of the SiC crystal and the other surface is the Si face of the SiC crystal. One surface, or both surfaces, can be polished and finished for use in device manufacturing. The outer edge 730 of the wafer 700 can be tapered, beveled, chamfered, square, round, etc.

The wafer 700 is cut from a doped SiC boule having a length that is significantly greater, (e.g., 10×, 20×, 50× 70× and greater) than the thickness 712 of wafer 700.

Thus, wafer 700 is not a thin doped type SiC layer that was grown or deposited on a substrate layer of a different type of material, from which the substrate layer is then removed. Such thin, e.g., less than 1 mm, less than 0.5 mm, substrate grow doped SiC layers, with the substrate removed, have vastly different electrical and physical properties from a doped SiC wafer cut from a doped SiC boule. Such substrate grown thin doped layers have unacceptable stresses within the material, exhibit warping and curvatures, and are in general not suitable for semiconductor device manufacturing of any kind.

### Example 5

A 6″ (150 mm) p-type SiC wafer. Polytype 4H. Dopant Al. Orientation<0001>+/−0.5 degrees. Thickness 325-500 μm. Bow<40 μm. Warp<60 μm. TTV<15 μm. SBIR (LTV) (10 mm×10 mm average)<4 μm. MPD (micropipes)<0.2 cm⁻². TSD (threading screw density)<500 cm⁻². BPD (basal plane dislocations)<500 cm⁻². Resistivity 0.015-0.028 ohm-cm.

### Example 6

A 6″ (150 mm) low resistivity p-type SiC wafer. Polytype 4H. Dopant Al. Orientation<0001>+/−0.5 degrees. Thickness 325-500 μm. Bow<40 μm. Warp<60 μm. TTV<15 μm. SBIR (LTV) (10 mm×10 mm average)<4 μm. MPD (micropipes)<0.2 cm⁻². TSD (threading screw density)<500 cm⁻². BPD (basal plane dislocations)<500 cm⁻². Resistivity 0.010-0.003 ohm-cm.

### Example 7

A 6″ (150 mm) p-type SiC wafer. Polytype 6H. Dopant Al. Orientation<0001>+/−0.5 degrees. Thickness 325-500 μm. Bow<40 μm. Warp<60 μm. TTV<15 μm. SBIR (LTV) (10 mm×10 mm average)<4 μm. MPD (micropipes)<0.2 cm⁻². TSD (threading screw density)<500 cm⁻². BPD (basal plane dislocations)<500 cm⁻². Resistivity 0.015-0.028 ohm-cm.

### Example 8

A 6″ (150 mm) low resistivity p-type SiC wafer. Polytype 6H. Dopant Al. Orientation<0001>+/−0.5 degrees. Thickness 325-500 μm. Bow<40 μm. Warp<60 μm. TTV<15 μm. SBIR (LTV) (10 mm×10 mm average)<4 μm. MPD (micropipes)<0.2 cm⁻². TSD (threading screw density)<500 cm⁻². BPD (basal plane dislocations)<500 cm⁻². Resistivity 0.010-0.003 ohm-cm.

### Example 9

A 6″ (150 mm) low resistivity n-type SiC wafer. Polytype 4H. Dopant P. Orientation<0001>+/−0.5 degrees. Thickness 325-500 μm. Bow<40 μm. Warp<60 μm. TTV<15 μm. SBIR (LTV) (10 mm×10 mm average)<4 μm. MPD (micropipes)<0.2 cm⁻². TSD (threading screw density)<500 cm⁻². BPD (basal plane dislocations)<500 cm⁻². Resistivity 0.010-0.003 ohm-cm.

### Example 10

A 6″ (150 mm) low resistivity n-type SiC wafer. Polytype 6H. Dopant P. Orientation<0001>+/−0.5 degrees. Thickness 325-500 μm. Bow<40 μm. Warp<60 μm. TTV<15 μm. SBIR (LTV) (10 mm×10 mm average)<4 μm. MPD (micropipes)<0.2 cm⁻². TSD (threading screw density)<500 cm⁻². BPD (basal plane dislocations)<500 cm⁻². Resistivity 0.010-0.003 ohm-cm.

### Example 11

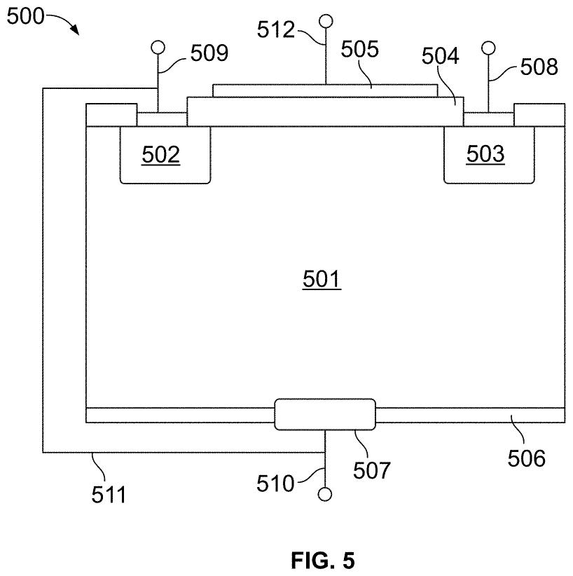

Turning to FIG. 5, there is shown a schematic of an N-channel E-MOSFET device 500 using a p-type SiC wafer. The device 500 has a gate 512, a metal electrode 505, a metal oxide layer 504. The device 500 has a source 509, a drain 508, and a body 510. A circuit 511 is formed between source 509 and body 510. The source 509 is connect through a metal electrode to an n-type SiC 502. The drain 508 is connected through a metal electrode to an n-type SiC 503. The device 500 has a p-type substrate 501, which is made from a p-type wafer cut from p-type boule. A metal oxide layer 507 is adjacent to the p-type substrate 501. The body 510 is connected through an electrode 507 to the p-type substrate 501.

### Example 12

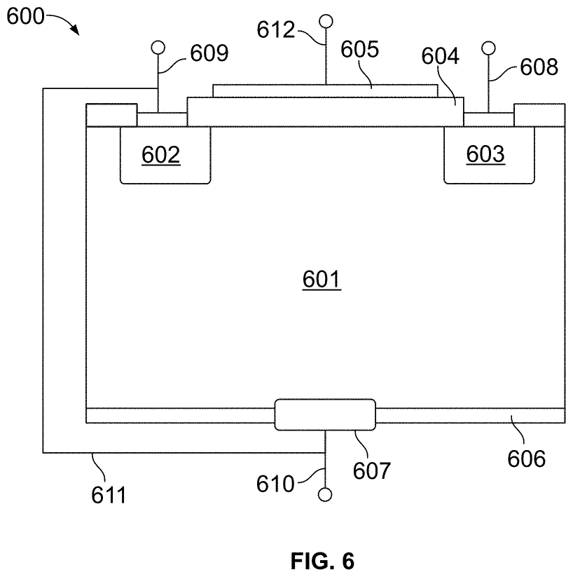

Turning to FIG. 6, there is shown a schematic of a P-channel E-MOSFET device 600 using a p-type SiC wafer. The device 600 has a gate 612, a metal electrode 605, a metal oxide layer 604. The device 600 has a source 609, a drain 608, and a body 610. A circuit 611 is formed between source 609 and body 610. The source 609 is connect through a metal electrode to an p-type SiC 602. The drain 608 is connected through a metal electrode to an p-type SiC 603. The p-type SiC 602, 603 are made from a p-type wafer cut from p-type boule. The device 600 has an n-type substrate 601. A metal oxide layer 607 is adjacent to the n-type substrate 601. The body 610 is connected through an electrode 607 to the n-type substrate 601.

### Example 13

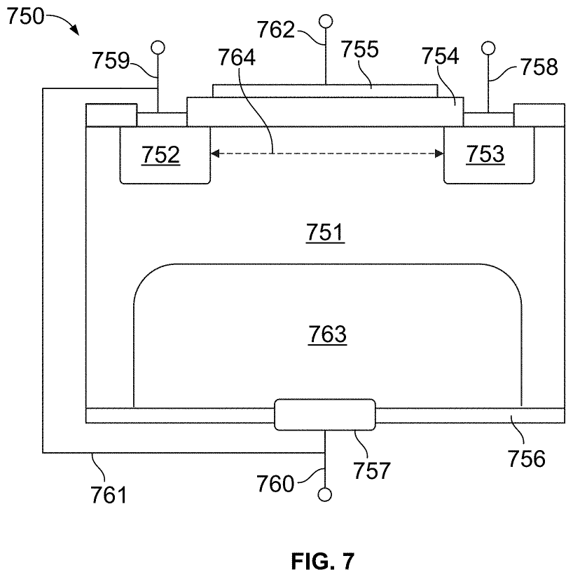

Turning to FIG. 7, there is shown a schematic of an N-channel D-MOSFET device 750 using a p-type SiC wafer. The device 750 has a gate 762, a metal electrode 755, a metal oxide layer 754. The device 750 has a source 759, a drain 758, and a body 760. A circuit 761 is formed between source 759 and body 760. The source 759 is connected through a metal electrode to an n-type SiC 752. The drain 758 is connected through a metal electrode to an n-type SiC 753. The device 750 has an N-Channel 751 having a channel length as shown by arrow 764. The device 750 has a p-type substrate 763, which is made from a p-type wafer cut from p-type boule. A metal oxide layer 756 is adjacent to the p-type substrate 763 and a portion of the N-channel 751. The body 760 is connected through an electrode 757 to the p-type substrate 763.

### Example 14

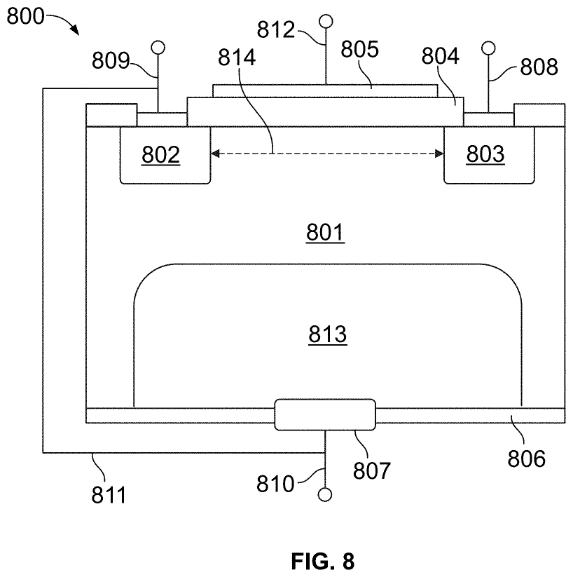

Turning to FIG. 8, there is shown a schematic of a P-channel D-MOSFET device 800 using a p-type SiC wafer. The device 800 has a gate 812, a metal electrode 805, a metal oxide layer 804. The device 800 has a source 809, a drain 808, and a body 810. A circuit 811 is formed between source 809 and body 810. The source 809 is connected through a metal electrode to an p-type SiC 802. The drain 808 is connected through a metal electrode to an p-type SiC 803. p-type SiC 802 and 803 are made from a p-type wafer cut from p-type boule. The device 800 has a P-Channel 801 made from a p-type wafer cut from p-type boule. Arrow 814 indicates the channel length. The device 800 has an n-type substrate 813. A metal oxide layer 806 is adjacent to the n-type substrate 813 and a portion of the P-channel 801. The base 810 is connected through an electrode 807 to the n-type substrate 813.

### Example 15

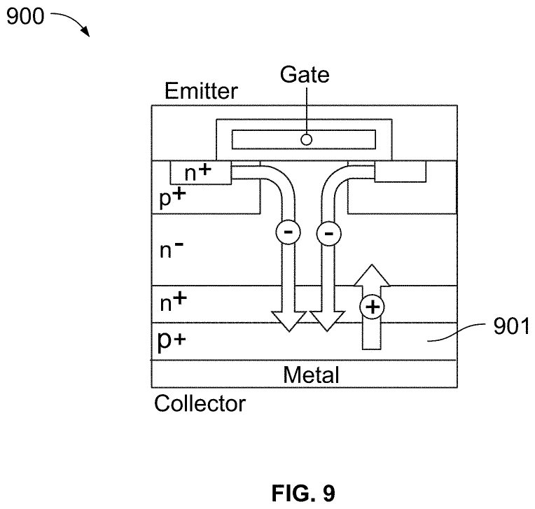

Turning to FIG. 9, there is shown a cross sectional schematic of an SiC IGBT device 900. The device 900 is based upon a p+ type wafer cut from p+ type boule, which forms layer 901, as well as the other p-type material in the multi-layered structure of the device 900. The other layers of the device may also be based upon PDC n-type SiC wafers.

### Example 16

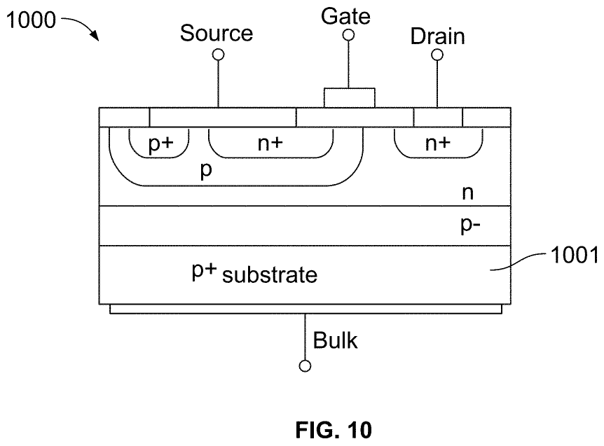

Turning to FIG. 10, there is shown a cross sectional schematic of an SiC Laterally Diffused MOSFET (LDMOS) device 1000. The device 1000 is based upon a p+ type wafer cut from p+ type boule, which forms layer 1001, as well as other the other p-type material in the multi-layered structure of the device 1000. The other layers of the device are may also be based upon the PDC n-type SiC wafers.

### Example 17

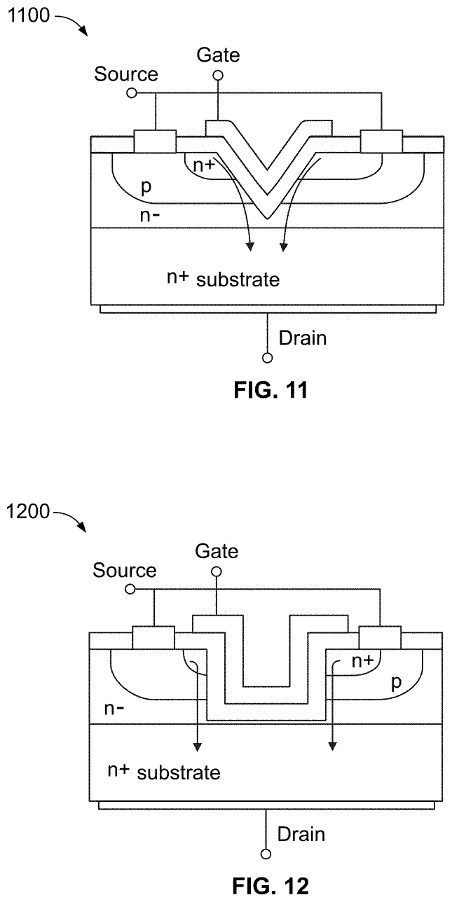

Turning to FIG. 11, there is shown a cross sectional schematic of an SiC VMOS MOSFET device 1100. The device 1100 is based upon a p-type wafer cut from p-type boule, which forms the p-type material in the multi-layered structure of the device 1100. The other layers of the device may also be based upon the PDC n-type SiC wafers.

### Example 18

Turning to FIG. 12, there is shown a cross sectional schematic of an SiC UMOS MOSFET device 1200. The device 1200 is based upon a p-type wafer cut from p-type boule, which forms the p-type material in the multi-layered structure of the device 1200. The other layers of the device may also be based upon the PDC n-type SiC wafers.

### Example 19

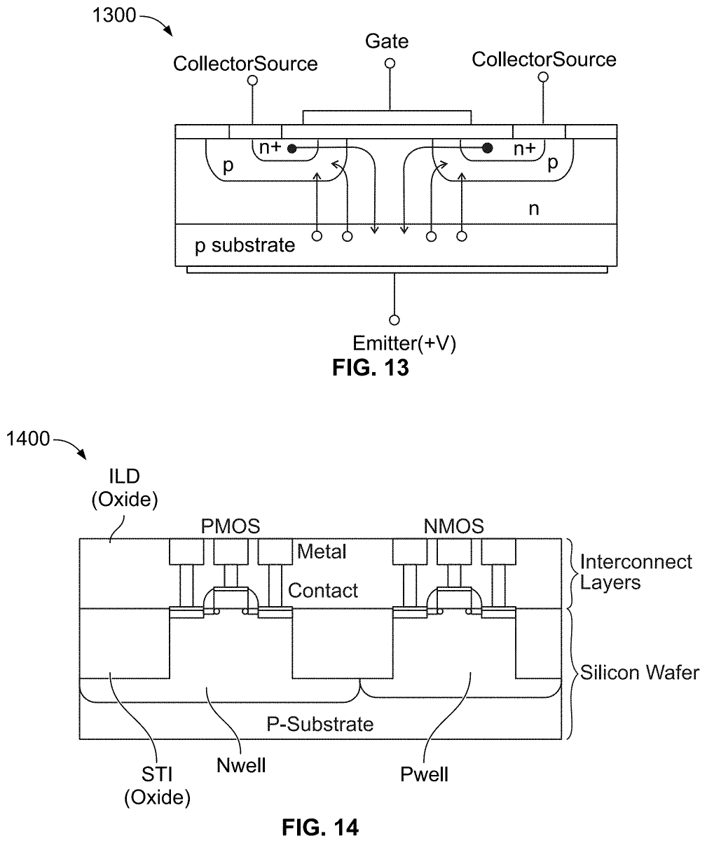

Turning to FIG. 13, there is shown a cross sectional schematic of an SiC IGBT device 1300. The device 1000 is based upon a p-type wafer cut from p-type boule, which forms the p substrate layer, as well as other the other p-type material in the multi-layered structure of the device 1300. The other layers of the device may also be based upon the PDC n-type SiC wafers.

### Example 20

Turning to FIG. 14, there is shown a cross sectional schematic of an SiC CMOS compound device 1400. The device 1400 is based upon a p-type wafer cut from p-type boule, which forms the p substrate layer in the multi-layered and component structure of the device 1400. Here a PMOS device and a NMOS device are built onto a common p-type substrate that is based upon a p-type wafer cut from p-type boule. Shallow trench isolation (ST) provides electrical isolation between these devices. Multiple levels of metal lines are routed to interconnect the devices and thus form a circuit on a chip. Capacitors, resistors and inductors can also be integrated into the compound device 1400.

### Example 21

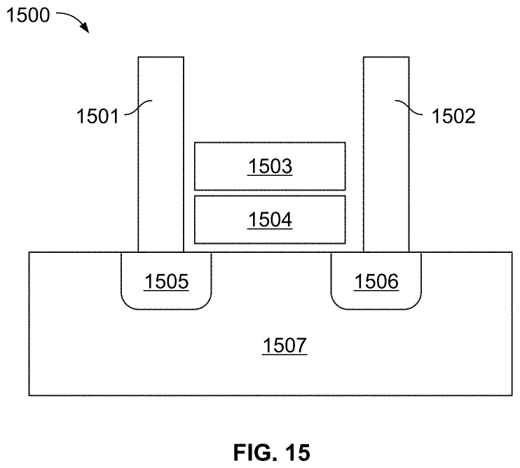

Turning to FIG. 15, there is shown a cross sectional schematic of an SiC flash memory device 1500. Prior to the present inventions, it is believed that, flash memory devices were not able to be built from SiC. The SiC flash memory device 1500 has a line source 1501, a bit line 1502, a world line control gate 1503, a float gate 1504, an n-type SiC component 1505, a second n-type SiC component 1506, and a p-type layer 1507, which layer is based on a p-type wafer cut from p-type boule.

### Example 22

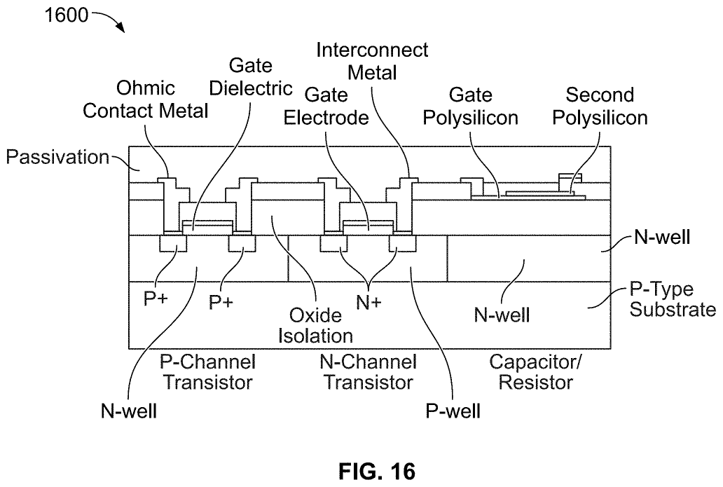

Turning to FIG. 16 there is shown an embodiment of an SiC CMOS compound device 1600. Such a device function as analogue and mixed signal devices. The device has a p-type substrate layer that is based upon the p-type wafer cut from p-type boule.

### Example 23

A lower resistivity SiC wafer, provides significant advantages when used to produce devices by eliminating the need for costly processing steps of (e.g., grinding or thinning the SiC substrate) while the same time requiring minimal, and preferably not requiring any, design changes to the circuitry.

### Example 24

A lower resistivity SiC wafer, also having a resistivity of between 1 and 5 milliohm-cm.

### Example 25

Nitrogen is quite a bit smaller than silicon. Thus, it is theorized that smaller impurity atoms are likely to occupy a carbon site, larger impurity atoms a silicon site in the crystal. During the SiC crystal growth nitrogen can take either or both Si or C sites in the crystal

Typically, a doped SiC wafer can have between 100-1,000 parts per million nitrogen dopant. It is theorized that only one out of every 100 nitrogen atoms supplied during growth is absorbed into the crystal, i.e., becomes an electrically active atomic impurity. Therefore, the source must be vastly higher than the desired dopant levels. (The dopants being “absorbed” into the lattice is known as site competition). However, there is a limit as to the amount of nitrogen that can be put into the crystal, too much and it will distort the crystal creating stress. In the past, higher concentrations of nitrogen doping to drive down resistivity have resulted in large numbers of stacking faults and other crystal quality defects negatively affecting epitaxy and device performance. Phosphorous is much closer in size to a silicon atom. Therefore, it is theorized that within the SiC crystalline lattice, phosphorous will replace silicon (as opposed to nitrogen replacing carbon) and will introduce vastly less stress (and less defects since defect formation is driven by stress in the crystal). Thus, it is theorized that based upon the dopant required, a preferred amount of phosphorous dopant would be <10% of the required nitrogen dopant in the source material for making a phosphorous doped n-type SiC wafer. In a preferred embodiment the process gets >1% of phosphorous from the source material into the SiC crystal as an electrically active atomic impurity.

### Example 26

In sublimation processes used to grow SiC crystals, typically there is more Si vapor than C vapor, making it amenable to incorporating nitrogen, but at the same time high Si vapor concentration does not lend itself to incorporating aluminum or boron for making a p-type material. Whereas, it is theorized that nitrogen or phosphorous, 1 out of every 100 atoms is incorporated as a dopant, for boron or aluminum only 1 out of every 1,000 atoms is incorporated.

Thus, for effective incorporation, it is theorized that doping sources should have equal or higher vapor pressure than silicon. Aluminum is a good dopant for p-type wafers, because it has higher vapor pressure than silicon. Aluminum and silicon sits next to one another on the periodic table (are virtually same size atoms).

### Example 27

The prior 4H silicon carbide p-type material, which were grown as an epitaxial layer on a substrate (which was typically an n-type SiC), that were available to fabricate n-channel IGBTs generally lack both the quality and conductivity to work well in the IGBT, and in particular, lack both the quality and conductivity to work as a commercially acceptable IGBT. The present inventions, among other things addresses and solves this problem by providing the p-type SiC wafers that are cut from p-type SiC boules, which wafers provide the ability to make commercially acceptable and operable SiC IGBT devices.

### Example 28

There has been a long standing need for an SiC LDMOSFETS (lateral metal-oxide-semiconductor field effect transistor). These devices were developed in silicon for high-power applications, such as cellular and UHF broadcast transmission, and the need for such device is ever increasing. This is because silicon LDMOSFETs offer higher gain and better linearity than bipolar devices. Yet, prior to the present inventions, this design, or type of device, could not be made with, or based upon, SiC, since there were only n-type SiC substrates and historically any p-type epitaxial formed SiC substrates had too high resistivity compared to silicon, leading to undesirable LDMOSFET device performance. The present inventions, among other things addresses and solves this problem by providing the p-type SiC wafers that are cut from p-type SiC boules, which wafers provide the ability to make commercially acceptable and operable SiC LDMOSFET devices.

### Example 29

A polysilocarb precursor formulation having one or more dopants that have a predetermined amount of acceptor impurity atoms and a predetermined amounts of donor impurity atoms. In this manner the SiC source material has predetermined amounts of acceptor and donor impurity atoms, and thus a predetermined ratio of acceptor and donor impurity atoms. This predetermined ratio, in turn provides a predetermined Nc value to a doped SiC grown from that source material.

### Example 30

In embodiments of the polysicocarb precursors Si—OH functional siloxanes and silanes are leveraged for much of the incorporation of Al—OH, P—OH, or B—OH functional groups without the evolution of hydrogen. For instance, as shown in following reaction:

˜Si—OH+˜B—OH→˜Si—O—B˜+H2O

### Example 31

An SiC IGBT having a voltage capability of greater than 10 kV, greater than 100 kV.

### Example 32

A medium voltage SiC IGBT having a voltage capability of around 2 kV.

### Example 33

A 4″ (100 mm) p-type SiC wafer. Polytype 4H. Dopant Al. Orientation<0001>+/−0.5 degrees. Thickness 325-500 μm. Bow<40 μm. Warp<60 μm. TTV<15 μm. SBIR (LTV) (10 mm×10 mm average)<4 μm. MPD (micropipes)<0.2 cm⁻². TSD (threading screw density)<500 cm⁻². BPD (basal plane dislocations)<500 cm⁻². Resistivity 0.015-0.028 ohm-cm.

### Example 34

A 4″ (100 mm) low resistivity p-type SiC wafer. Polytype 4H. Dopant Al. Orientation<0001>+/−0.5 degrees. Thickness 325-500 μm. Bow<40 μm. Warp<60 μm. TTV<15 μm. SBIR (LTV) (10 mm×10 mm average)<4 μm. MPD (micropipes)<0.2 cm⁻². TSD (threading screw density)<500 cm⁻². BPD (basal plane dislocations)<500 cm⁻². Resistivity 0.010-0.003 ohm-cm.

### Example 35

A 6″ (150 mm) p-type SiC wafer. Polytype 6H. Dopant Al. Orientation<0001>+/−0.5 degrees. Thickness 325-500 μm. Bow<40 μm. Warp<60 μm. TTV<15 μm. SBIR (LTV) (10 mm×10 mm average)<4 μm. MPD (micropipes)<0.2 cm⁻². TSD (threading screw density)<500 cm⁻². BPD (basal plane dislocations)<500 cm⁻². Resistivity 0.015-0.028 ohm-cm.

### Example 36

A 6″ (150 mm) low resistivity p-type SiC wafer. Polytype 6H. Dopant Al. Orientation<0001>+/−0.5 degrees. Thickness 325-500 μm. Bow<40 μm. Warp<60 μm. TTV<15 μm. SBIR (LTV) (10 mm×10 mm average)<4 μm. MPD (micropipes)<0.2 cm⁻². TSD (threading screw density)<500 cm⁻². BPD (basal plane dislocations)<500 cm⁻². Resistivity 0.010-0.003 ohm-cm.

### Example 37

A 4″ (100 mm) p-type SiC wafer. Polytype 4H. Dopant Al. Orientation<0001>+/−0.5 degrees. Thickness 325-500 μm. Bow<40 μm. Warp<60 μm. TTV<15 μm. SBIR (LTV) (10 mm×10 mm average)<4 μm. MPD (micropipes)<0.2 cm⁻². TSD (threading screw density)<500 cm⁻². BPD (basal plane dislocations)<500 cm⁻². The wafer an N_{A} from 10¹⁸/cm³ to about 10¹⁹/cm³

### Example 38

A 6″ (150 mm) p-type SiC wafer. Polytype 4H. Dopant Al. Orientation<0001>+/−0.5 degrees. Thickness 325-500 μm. Bow<40 μm. Warp<60 μm. TTV<15 μm. SBIR (LTV) (10 mm×10 mm average)<4 μm. MPD (micropipes)<0.2 cm⁻². TSD (threading screw density)<500 cm⁻². BPD (basal plane dislocations)<500 cm⁻². The wafer an N_{A} from 10¹⁸/cm³ to about 10¹⁹/cm³

### Example 39

A 6″ (150 mm) p-type SiC wafer. Polytype 6H. Dopant Al. Orientation<0001>+/−0.5 degrees. Thickness 325-500 μm. Bow<40 μm. Warp<60 μm. TTV<15 μm. SBIR (LTV) (10 mm×10 mm average)<4 μm. MPD (micropipes)<0.2 cm⁻². TSD (threading screw density)<500 cm⁻². BPD (basal plane dislocations)<500 cm⁻². The wafer an N_{A} from 10¹⁸/cm³ to about 10¹⁹/cm³

### Example 40

A 4″ (100 mm) p-type SiC wafer. Polytype 4H. Dopant Al. Orientation<0001>+/−0.5 degrees. Thickness 325-500 μm. Bow<40 μm. Warp<60 μm. TTV<15 μm. SBIR (LTV) (10 mm×10 mm average)<4 μm. MPD (micropipes)<0.2 cm⁻². TSD (threading screw density)<500 cm⁻². BPD (basal plane dislocations)<500 cm⁻². The wafer an N_{A} from 10¹⁸/cm³ to about 10¹⁹/cm³

### Example 41

A 4″ (100 mm) p-type SiC wafer. Polytype 6H. Dopant Al. Orientation<0001>+/−0.5 degrees. Thickness 325-500 μm. Bow<40 μm. Warp<60 μm. TTV<15 μm. SBIR (LTV) (10 mm×10 mm average)<4 μm. MPD (micropipes)<0.2 cm⁻². TSD (threading screw density)<500 cm⁻². BPD (basal plane dislocations)<500 cm⁻². The wafer an N_{A} from 10¹⁸/cm³ to about 10¹⁹/cm³

### Example 42

A 4″ (100 mm) low resistivity n-type SiC wafer. Polytype 4H. Dopant P. Orientation<0001>+/−0.5 degrees. Thickness 325-500 μm. Bow<40 μm. Warp<60 μm. TTV<15 μm. SBIR (LTV) (10 mm×10 mm average)<4 μm. MPD (micropipes)<0.2 cm⁻². TSD (threading screw density)<500 cm⁻². BPD (basal plane dislocations)<500 cm⁻². Resistivity 0.010-0.003 ohm-cm.

### Example 43

A 4″ (100 mm) low resistivity p-type SiC wafer. Polytype 6H. Dopant P. Orientation<0001>+/−0.5 degrees. Thickness 325-500 μm. Bow<40 μm. Warp<60 μm. TTV<15 μm. SBIR (LTV) (10 mm×10 mm average)<4 μm. MPD (micropipes)<0.2 cm⁻². TSD (threading screw density)<500 cm⁻². BPD (basal plane dislocations)<500 cm⁻². Resistivity 0.010-0.003 ohm-cm.

### Example 44

A 6″ (150 mm) low resistivity n-type SiC wafer. Polytype 4H. Dopant P. Orientation<0001>+/−0.5 degrees. Thickness 325-500 μm. Bow<40 μm. Warp<60 μm. TTV<15 μm. SBIR (LTV) (10 mm×10 mm average)<4 μm. MPD (micropipes)<0.2 cm⁻². TSD (threading screw density)<500 cm⁻². BPD (basal plane dislocations)<500 cm⁻². Resistivity 0.010-0.003 ohm-cm.

### Example 45

A 6″ (150 mm) low resistivity p-type SiC wafer. Polytype 6H. Dopant P. Orientation<0001>+/−0.5 degrees. Thickness 325-500 μm. Bow<40 μm. Warp<60 μm. TTV<15 μm. SBIR (LTV) (10 mm×10 mm average)<4 μm. MPD (micropipes)<0.2 cm⁻². TSD (threading screw density)<500 cm⁻². BPD (basal plane dislocations)<500 cm⁻². Resistivity 0.010-0.003 ohm-cm.

### Example 46

A 4″ (100 mm) low resistivity n-type SiC wafer. Polytype 4H. Dopant P. Orientation<0001>+/−0.5 degrees. Thickness 325-500 μm. Bow<40 μm. Warp<60 μm. TTV<15 μm. SBIR (LTV) (10 mm×10 mm average)<4 μm. MPD (micropipes)<0.2 cm⁻². TSD (threading screw density)<500 cm⁻². BPD (basal plane dislocations)<500 cm⁻². Resistivity 0.010-0.003 ohm-cm.

### Example 47

A 4″ (100 mm) low resistivity p-type SiC wafer. Polytype 6H. Dopant p. Orientation<0001>+/−0.5 degrees. Thickness 325-500 μm. Bow<40 μm. Warp<60 μm. TTV<15 μm. SBIR (LTV) (10 mm×10 mm average)<4 μm. MPD (micropipes)<0.2 cm⁻². TSD (threading screw density)<500 cm⁻². BPD (basal plane dislocations)<500 cm⁻². Resistivity 0.010-0.003 ohm-cm.

### Example 48

A 6″ (150 mm) low resistivity n-type SiC wafer. Polytype 4H. Dopant P. Orientation<0001>+/−0.5 degrees. Thickness 325-500 μm. Bow<40 μm. Warp<60 μm. TTV<15 μm. SBIR (LTV) (10 mm×10 mm average)<4 μm. MPD (micropipes)<0.2 cm⁻². TSD (threading screw density)<500 cm⁻². BPD (basal plane dislocations)<500 cm⁻². Resistivity 0.010-0.003 ohm-cm.

### Example 49

A 6″ (150 mm) low resistivity p-type SiC wafer. Polytype 6H. Dopant P. Orientation<0001>+/−0.5 degrees. Thickness 325-500 μm. Bow<40 μm. Warp<60 μm. TTV<15 μm. SBIR (LTV) (10 mm×10 mm average)<4 μm. MPD (micropipes)<0.2 cm⁻². TSD (threading screw density)<500 cm⁻². BPD (basal plane dislocations)<500 cm⁻². Resistivity 0.010-0.003 ohm-cm.

### HEADINGS AND EMBODIMENTS

It should be understood that the use of headings in this specification is for the purpose of clarity, and is not limiting in any way. Thus, the processes and disclosures described under a heading should be read in context with the entirely of this Specification, including the various examples. The use of headings in this specification should not limit the scope of protection afford the present inventions.

It is noted that there is no requirement to provide or address the theory underlying the novel and groundbreaking processes, materials, performance or other beneficial features and properties that are the subject of, or associated with, embodiments of the present inventions. Nevertheless, various theories are provided in this specification to further advance the art in this area. These theories put forth in this specification, and unless expressly stated otherwise, in no way limit, restrict or narrow the scope of protection to be afforded the claimed inventions. These theories many not be required or practiced to utilize the present inventions. It is further understood that the present inventions may lead to new, and heretofore unknown theories to explain the function-features of embodiments of the methods, articles, materials, devices and system of the present inventions; and such later developed theories shall not limit the scope of protection afforded the present inventions.

The various embodiments of formulations, compositions, articles, plastics, ceramics, materials, parts, wafers, boules, volumetric structure, uses, applications, equipment, methods, activities, and operations set forth in this specification may be used for various other fields and for various other activities, uses and embodiments. Additionally, these embodiments, for example, may be used with: existing systems, articles, compositions, materials, operations or activities; may be used with systems, articles, compositions, materials operations or activities that may be developed in the future; and with such systems, articles, compositions, materials, operations or activities that may be modified, in-part, based on the teachings of this specification. Further, the various embodiments and examples set forth in this specification may be used with each other, in whole or in part, and in different and various combinations. Thus, for example, the configurations provided in the various embodiments of this specification may be used with each other. For example, the components of an embodiment having A, A′ and B and the components of an embodiment having A″, C and D can be used with each other in various combination, e.g., A, C, D, and A. A″ C and D, etc., in accordance with the teaching of this specification. Thus, the scope of protection afforded the present inventions should not be limited to a particular embodiment, configuration or arrangement that is set forth in a particular embodiment, example, or in an embodiment in a particular Figure.

The invention may be embodied in other forms than those specifically disclosed herein without departing from its spirit or essential characteristics. The described embodiments are to be considered in all respects only as illustrative and not restrictive.

1. A doped polysilocarb precursor material, for use in making a doped SiC crystal, the precursor material comprising:
a. a dopant, wherein the dopant comprises a number of donor atoms, a number of acceptor atoms or both;
b. silicon, carbon, and oxygen;
c. wherein the dopant is about 10% or less by weight of a total weight of the doped polysilocarb precursor material;
d. wherein the dopant is covalently bonded to at least one of silicon, carbon or oxygen;
e. wherein the doped polysilocarb precursor material defines a potential net carrier concentration (pNC); wherein pNC=the number of donor atoms−the number of acceptor atoms.

2. The doped polysilocarb precursor material of claim 1, wherein the pNC is positive.

3. The doped polysilocarb precursor material of claim 2, wherein there are at least 1×10¹⁸ more donor atoms than acceptor atoms.

4. The doped polysilocarb precursor material of claim 3, wherein the number of acceptor atoms is less than 1×10¹⁴.

5. The doped polysilocarb precursor material of claim 3, wherein the number of acceptor atoms is less than 1×10¹⁰.

6. The doped polysilocarb precursor material of claim 1, wherein the donor atoms are selected from one or more of the elements in Group 15 of the periodic table.

7. The doped polysilocarb precursor material of claim 1, wherein the donor atoms comprise phosphorous.

8. The doped polysilocarb precursor material of claim 1, wherein the donor atoms consist essentially of phosphorous.

9. The doped polysilocarb precursor material of claim 1, wherein the donor atom comprises phosphorous; wherein the covalent bond is formed with phosphorous; and, the polysilocarb precursor further comprising one or more of:
a. ˜Si—O—P—R, where R is an alkyl group, a phenyl group, or a styrenyl group;
b. ˜Si—C—C—P—R, wherein R is an alkene group, a styrenyl group, an alkyl group or a phenyl group; and,
c. (˜Si—O)₃—P═O.

10. The doped polysilocarb precursor material of claim 1, wherein the precursor material is a cured solid material.

11. The doped polysilocarb precursor material of claim 1, wherein the pNC is negative.

12. The doped polysilocarb precursor material of claim 2, wherein there are at least 1×10¹⁸ more acceptor atoms than donor atoms.

13. The doped polysilocarb precursor material of claim 3, wherein the number of donor atoms is less than 1×10¹⁴.

14. The doped polysilocarb precursor material of claim 3, wherein the number of donor atoms is less than 1×10¹⁰.

15. The doped polysilocarb precursor material of claim 11, wherein the acceptor atoms are selected from one or more of the elements in Group 13 of the periodic table.

16. The doped polysilocarb precursor material of claim 1, wherein the acceptor atoms comprise boron.

17. The doped polysilocarb precursor material of claim 11, wherein the acceptor atoms consist essentially of boron.

18. The doped polysilocarb precursor material of claim 1, wherein the acceptor atoms comprise aluminum.

19. The doped polysilocarb precursor material of claim 11, wherein the acceptor atoms consist essentially of aluminum.

20. The doped polysilocarb precursor material of claim 11, wherein the acceptor atoms comprise aluminum; and wherein the precursor material contains no alloys, and is thereby alloy free.

21. The doped polysilocarb precursor material of claim 11, wherein the acceptor atoms consist essentially of aluminum; and wherein the precursor material contains no alloys, and is thereby alloy free.

22. The doped polysilocarb precursor material of claim 1, wherein the precursor material contains no alloys, and is thereby alloy free.

23. The doped polysilocarb precursor material of claim 1, wherein the acceptor atom comprises aluminum; wherein the covalent bond is formed with aluminum; and, the polysilocarb precursor further comprising one or more of:
a. 2Al—(O—Si˜)₃;
b. 2Al—(O—Si˜)₃; and,
c. Al₂O₃.

24. The doped polysilocarb precursor material of claim 1, wherein the acceptor atom comprises boron; wherein the covalent bond is formed with boron; and, the polysilocarb precursor further comprising one or more of:
a. 2B—(O—Si˜)₃; and,
b. B—C—C—Si˜.

25. The doped polysilocarb precursor material of claim 11, wherein the precursor material is a cured solid material.

26. A doped shaped charge source material, for use in making a p-type SiC crystal, the shaped charge source material comprising:
a. a porous matrix comprising Si, C and a number of impurity atoms, wherein the impurity atoms comprise a number of donor atoms, a number of acceptor atoms or both;
b. wherein the impurity atoms are less than 5% by weight of a total weight of the doped shaped charge source material; and,
c. wherein the doped shaped charge source material defines a potential net carrier concentration (pNC); wherein pNC=the number of donor atoms−the number of acceptor atoms.

27. The doped shaped charge source material of claim 26, wherein the pNC is positive.

28. The doped shaped charge source material of claim 26, wherein there are at least 1×10¹⁸ more donor atoms than acceptor atoms.

29. The doped shaped charge source material of claim 26, wherein the number of acceptor atoms is less than 1×10¹⁴.

30. The doped shaped charge source material of claim 26, wherein the number of acceptor atoms is less than 1×10¹⁰.

31. The doped shaped charge source material of claim 26, wherein the donor atoms are selected from one or more of the elements in Group 15 of the periodic table.

32. The doped shaped charge source material of claim 26, wherein the donor atoms comprise phosphorous.

33. The doped shaped charge source material of claim 26, wherein the donor atoms consist essentially of phosphorous.

34. The doped shaped charge source material of claim 26, wherein the pNC is negative.

35. The doped shaped charge source material of claim 26, wherein there are at least 1×10¹⁸ more acceptor atoms than donor atoms.

36. The doped shaped charge source material of claim 26, wherein the number of donor atoms is less than 1×10¹⁴.

37. The doped shaped charge source material of claim 26, wherein the number of donor atoms is less than 1×10¹⁰.

38. The doped shaped charge source material of claim 26, wherein the acceptor atoms are selected from one or more of the elements in Group 13 of the periodic table.

39. The doped shaped charge source material of claim 26, wherein the acceptor atoms comprise boron.

40. The doped shaped charge source material of claim 34, wherein the acceptor atoms consist essentially of boron.

41. The doped shaped charge source material of claim 26, wherein the acceptor atoms comprise aluminum.

42. The doped shaped charge source material of claim 34, wherein the acceptor atoms consist essentially of aluminum.

43. The doped shaped charge source material of claim 34, wherein the acceptor atoms comprise aluminum; and wherein the precursor material contains no alloys, and is thereby alloy free.

44-77. (canceled)
